(19) United States
(12) Patent Application Publication
(10) Pub. No.: US 2026/0282673 A1
(43) Pub. Date: Sep. 17, 2026

(54) DISPLAY APPARATUS AND ELECTRONIC APPARATUS INCLUDING THE SAME

(71) Applicant: Samsung Display Co., Ltd., Yongin-si (KR)

(72) Inventors: Sola Lee, Yongin-si (KR); Changwoo Kwon, Yongin-si (KR); Eunhye Kim, Yongin-si (KR); Jiyun Park, Yongin-si (KR); Seongjun Lee, Yongin-si (KR)

(21) Appl. No.: 19/562,534

(22) Filed: Mar. 10, 2026

(30) Foreign Application Priority Data
Mar. 14, 2025 (KR) 10-2025-0033594

(51) Int. Cl. H10K 59/126; H10K 59/131; H10K 59/65; H10K 59/80

(52) U.S. Cl. CPC H10K 59/126; H10K 59/131; H10K 59/65; H10K 59/8792

(57) ABSTRACT

A display apparatus may include a substrate including a component area, which includes a sub-display area and a transmission area, and a main display area at least partially around (e.g., surrounding) the component area, a display layer including a main light-emitting element in the main display area and a sub-light-emitting element in the sub-display area, and a light control layer on the display layer, including a first light-blocking layer and a second light-blocking layer under the first light-blocking layer, wherein the first light-blocking layer includes a plurality of first light-blocking lines extending in a first direction and including a first light-blocking material, and the second light-blocking layer includes a plurality of second light-blocking lines extending in the first direction and including a second light-blocking material, wherein an infrared light transmittance of the first light-blocking material is higher than an infrared light transmittance of the second light-blocking material.

### CROSS-REFERENCE TO RELATED APPLICATION

The present application claims priority to and the benefit of Korean Patent Application No. 10-2025-0033594, filed on March 14, 2025, in the Korean Intellectual Property Office, the entire disclosure of which is incorporated herein by reference.

### BACKGROUND

### 1 . Field

One or more embodiments of the present disclosure relate to a display apparatus and an electronic apparatus including such a display apparatus.

### 2. Description of the Related Art

Display apparatuses are increasingly being used in a wide variety of applications. As their thickness and weight have decreased, their applicability has expanded across numerous fields. With this expansion, there is growing demand for display apparatuses capable of delivering enhanced image quality and higher resolution. Recently, display apparatuses have been integrated into vehicles to provide visual information to users in the driver’s seat and passenger seats.

### SUMMARY

Light emitted from a display apparatus arranged inside a vehicle may be reflected by a window of the vehicle to reach the user. In such cases, the reflected light may obstruct the driver’s field of view, potentially leading to safety concerns. Additionally, if (e.g., when) a camera or sensor for driver monitoring is positioned on the display apparatus, it may be desirable to place the camera or sensor within the display area to improve recognition accuracy.

One or more aspects of embodiments of the present disclosure are directed toward a display apparatus with improved or enhanced display quality and improved or enhanced sensor efficiency so as not to interfere with a user's field of view, and an electronic apparatus including the display apparatus. However, this is merely an example, and the scope of the present disclosure is not limited thereby.

Additional aspects of embodiments will be set forth in part in the description which follows and, in part, will be apparent from the description or may be learned by practice of the presented embodiments of the disclosure.

According to one or more embodiments, a display apparatus includes a substrate including a component area including a sub-display area and a transmission area, and a main display area at least partially around (e.g., surrounding) the component area, a display layer including a main light-emitting element arranged in the main display area and a sub-light-emitting element arranged in the sub-display area, and a light control layer arranged on the display layer and including a first light-blocking layer and a second light-blocking layer arranged under the first light-blocking layer, wherein the first light-blocking layer includes a plurality of first light-blocking lines extending in a first direction and including a first light-blocking material, and the second light-blocking layer includes a plurality of second light-blocking lines extending in the first direction and including a second light-blocking material, wherein an infrared light transmittance of the first light-blocking material is higher than an infrared light transmittance of the second light-blocking material.

According to one or more embodiments, the plurality of first light-blocking lines may be spaced and/or apart (e.g., spaced apart or separated) from each other in a second direction crossing the first direction, and the plurality of second light-blocking lines may be spaced and/or apart (e.g., spaced apart or separated) from each other in the second direction.

According to one or more embodiments, at least one first light-blocking line among the plurality of first light-blocking lines and at least one second light-blocking line among the plurality of second light-blocking lines may overlap each other in plan view.

According to one or more embodiments, the first light-blocking material may have a transmittance in a range of 90% to 100% for light having a wavelength of 940 nm.

According to one or more embodiments, the first light-blocking material may include at least one selected from among Lactam Black, Perlene Black, and Aniline Black.

According to one or more embodiments, the second light-blocking material may include at least one selected from among carbon black, black pigment, and black dye.

According to one or more embodiments, the light control layer may further include a third light-blocking layer arranged under the second light-blocking layer, and a fourth light-blocking layer arranged under the third light-blocking layer, wherein the third light-blocking layer may include a plurality of third light-blocking lines extending in the first direction, and the fourth light-blocking layer may include a plurality of fourth light-blocking lines extending in the first direction.

According to one or more embodiments, the plurality of third light-blocking lines and the plurality of fourth light-blocking lines may include substantially the same material as the second light-blocking material.

According to one or more embodiments, the plurality of first light-blocking lines and the plurality of second light-blocking lines may be arranged in the main display area and the sub-display area.

According to one or more embodiments, the light control layer may further include a plurality of sub-light-blocking lines arranged in the transmission area and extending in the first direction, and the plurality of sub-light-blocking lines may be arranged on substantially the same layer as the plurality of first light-blocking lines and may include substantially the same material as the first light-blocking material.

According to one or more embodiments, the light control layer may further include a sub-light-blocking pattern covering an entire (e.g., substantially entire) surface of the transmission area, and the sub-light-blocking pattern may be arranged on substantially the same layer as the plurality of first light-blocking lines and may include substantially the same material as the first light-blocking material.

According to one or more embodiments, the light control layer on the transmission area may not include a (e.g., any) light-blocking material.

According to one or more embodiments, the plurality of first light-blocking lines and the plurality of second light-blocking lines may be arranged in the main display area, and the light control layer on the component area may not include a (e.g., any) light-blocking material.

According to one or more embodiments, the display apparatus may further include a signal wiring configured or arranged to transmit an electrical signal to: a main pixel circuit electrically connected to the main light-emitting element; or a sub-pixel circuit electrically connected to the sub-light-emitting element, wherein the signal wiring may extend in a second direction crossing the first direction, and the light control layer may further include a vertical light-blocking line overlapping the signal wiring in plan view.

According to one or more embodiments, a display apparatus includes a substrate including a component area including a sub-display area and a transmission area, and a main display area at least partially around (e.g., surrounding) the component area, a display layer including a main light-emitting element arranged in the main display area and a sub-light-emitting element arranged in the sub-display area, and a light control layer arranged on the display layer and including a plurality of first light-blocking lines extending in a first direction, wherein the plurality of first light-blocking lines are arranged in each of the main display area, the sub-display area, and the transmission area, and the plurality of first light-blocking lines have a transmittance in a range of 90 % to 100 % for light having a wavelength of 940 nm.

According to one or more embodiments, each of the plurality of first light-blocking lines may include at least one selected from among Lactam Black, Perlene Black, and Aniline Black.

According to one or more embodiments, the light control layer may further include a plurality of second light-blocking lines arranged under the plurality of first light-blocking lines, wherein the plurality of second light-blocking lines may be arranged in the main display area and the sub-display area, and an infrared light transmittance of the plurality of second light-blocking lines may be lower than an infrared light transmittance of the plurality of first light-blocking lines.

According to one or more embodiments, each of the plurality of second light-blocking lines may include at least one selected from among carbon black, black pigment, and black dye.

According to one or more embodiments, an electronic apparatus includes a display apparatus including a component area including a sub-display area and a transmission area, and a main display area at least partially around (e.g., surrounding) the component area, and a component arranged to overlap the component area, wherein the display apparatus includes a substrate, a display layer including a main light-emitting element arranged in the main display area and a sub-light-emitting element arranged in the sub-display area; and a light control layer arranged on the display layer and including a first light-blocking layer and a second light-blocking layer arranged under the first light-blocking layer, wherein the first light-blocking layer includes a plurality of first light-blocking lines extending in a first direction and including a first light-blocking material, and the second light-blocking layer includes a plurality of second light-blocking lines extending in the first direction and including a second light-blocking material, wherein an infrared light transmittance of the first light-blocking material is higher than an infrared light transmittance of the second light-blocking material.

According to one or more embodiments, the component may include a camera or a sensor.

The configuration or arrangement of the display apparatus as described herein enables improved or enhanced integration of optical components, such as cameras or sensors, within the display area without significantly or substantially degrading display performance or obstructing the user’s field of view. By employing a multi-layered light control structure with differentiated infrared transmittance properties, the apparatus may selectively manage visible and infrared light transmission. This allows for enhanced sensor efficiency, for example, in driver monitoring systems, while maintaining high display quality and reducing visual artifacts. The arrangement of light-blocking lines across the main display, sub-display, and transmission areas further contributes to uniform (e.g., substantially uniform) optical performance and supports compact, multifunctional electronic devices, such as in-vehicle displays or smart devices with embedded sensing capabilities.

### BRIEF DESCRIPTION OF THE DRAWINGS

The above and other aspects and features of certain embodiments of the present disclosure will be more apparent from the following description taken in conjunction with the accompanying drawings, in which:

FIG. 1 schematically illustrates the exterior of a vehicle including a display apparatus, according to one or more embodiments;

FIG. 2 schematically illustrates the interior of a vehicle including a display apparatus, according to one or more embodiments;

FIG. 3 is a schematic plan view of a display apparatus according to one or more embodiments;

FIG. 4 is a cross-sectional view of the display apparatus taken along the line I-I' of FIG. 3, according to one or more embodiments;

FIG. 5 is a schematic equivalent circuit diagram of a light-emitting diode provided in one sub-pixel and a sub-pixel circuit connected to the light-emitting diode of a display apparatus, according to one or more embodiments;

FIGS. 6A and 6B are plan views schematically illustrating a main display area of a display apparatus, according to one or more embodiments;

FIG. 7 is a schematic plan view of a component area of a display apparatus, according to one or more embodiments;

FIG. 8 is a cross-sectional view schematically illustrating a portion of a display apparatus, according to one or more embodiments;

FIG. 9 is a schematic plan view of a component area of a display apparatus, according to one or more embodiments;

FIG. 10 is a cross-sectional view schematically illustrating a portion of a display apparatus, according to one or more embodiments;

FIG. 11 is a schematic plan view of a component area of a display apparatus, according to one or more embodiments;

FIG. 12 is a cross-sectional view schematically illustrating a portion of a display apparatus, according to one or more embodiments;

FIG. 13 is a schematic plan view of a display area of a display apparatus, according to one or more embodiments;

FIG. 14 is a block diagram of an electronic apparatus according to one or more embodiments; and

FIG. 15 is a schematic diagram of electronic apparatuses according to one or more embodiments.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present disclosure to those skilled in the art.

As the present description allows for one or more suitable changes to the disclosed subject matter and embodiments, certain embodiments will be illustrated in the accompanying drawings and described in more detail in the written description. The aspects, effects, and/or embodiments of the present disclosure and methods of achieving them will be clarified with reference to one or more embodiments and the accompanying drawings described in more detail. However, the disclosure is not limited to the disclosed embodiments and may be embodied in one or more suitable forms.

The utilization of “may” if (e.g., when) describing embodiments of the present disclosure refers to “one or more embodiments of the present disclosure.”

As used herein, the term "and/or" includes any and all combinations of one or more of the associated listed items.

In the context of the present application and unless otherwise defined, the terms "use," "using," and "used" may be considered synonymous with the terms "utilize," "utilizing," and "utilized," respectively.

Throughout the present disclosure, the expressions, such as “at least one of,” “one of,” and “selected from,” if (e.g., when) preceding a list of elements, modify the entire list of elements and do not modify the individual elements of the list. For example, "at least one of a, b, or c," “at least one selected from among a, b, and c,” "at least one selected from among a to c," and/or the like indicates only a, only b, only c, both (e.g., simultaneously) a and b, both (e.g., simultaneously) a and c, both (e.g., simultaneously) b and c, all of a, b, and c, or variations thereof.

It will be understood that although the terms "first," "second," and/or the like may be used herein to describe one or more suitable elements, these elements should not be limited by these terms. These terms are only used to distinguish one element from another.

The singular forms "a," "an," and "the" as used herein are intended to include the plural forms as well unless the context clearly indicates otherwise.

It will be further understood that the terms “includes,” “has,” “including,” and/or “having” used herein specify the presence of stated features or elements, but do not preclude the presence or addition of one or more other features or elements. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

It will be further understood that, if (e.g., when) a layer, a region, or an element is referred to as being "on" another layer, region, or element, it may be directly or indirectly on the other layer, region, or element. For example, intervening layers, regions, or elements may be present therebetween. In contrast, if (e.g., when) a layer, a region, or an element is referred to as being “directly on” another layer, region, or element, there are no intervening layers, regions, or elements present therebetween.

Sizes of elements in the drawings may be exaggerated or reduced for convenience of explanation. For example, because sizes and thicknesses of elements in the drawings are arbitrarily illustrated for convenience of explanation, embodiments of the present disclosure are not limited thereto.

If (e.g., when) a certain embodiment is referred to as being implemented differently, a set or specific process order may be performed differently from the described order. For example, two consecutively described processes may be performed substantially at the same time or performed in an order opposite to the described order.

It will be further understood that, if (e.g., when) layers, regions, or components are referred to as being connected to each other, they may be directly connected to each other or indirectly connected to each other with intervening layers, regions, or components therebetween. For example, if (e.g., when) layers, regions, or components are referred to as being electrically connected to each other, they may be directly electrically connected to each other or indirectly electrically connected to each other with intervening layers, regions, or components therebetween.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

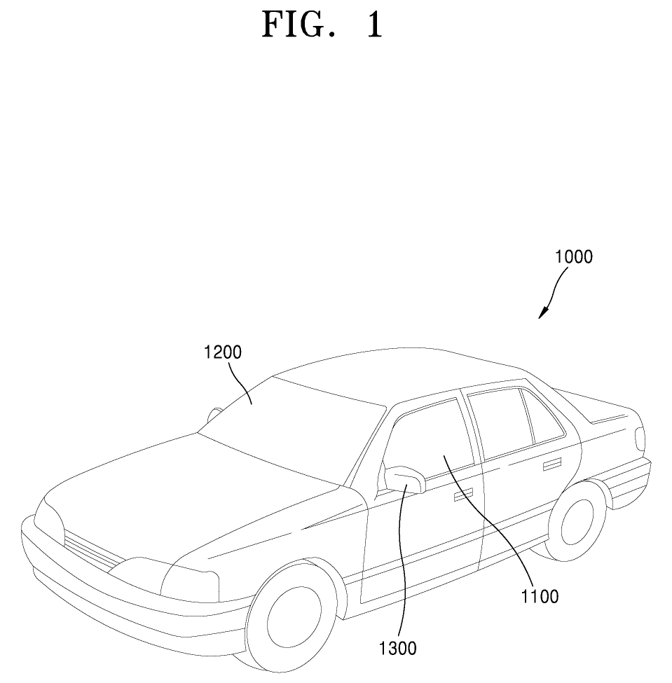

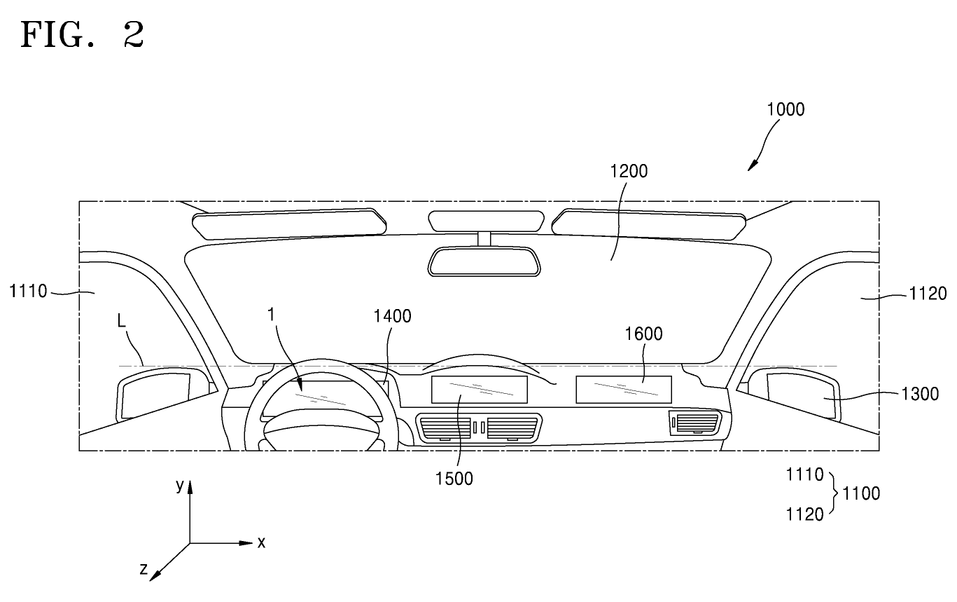

FIG. 1 schematically illustrates the exterior of a vehicle including a display apparatus, according to one or more embodiments. FIG. 2 schematically illustrates the interior of a vehicle including a display apparatus, according to one or more embodiments.

Referring to FIGS. 1 and FIG. 2, a vehicle 1000 may refer to one or more suitable devices to move a transport target object, for example, a human, a product, or an animal, from a departure point to a destination. The vehicle 1000 may include a car driving on a road or track, a vessel moving over the sea or a river, and/or an airplane flying through the air using the action of airflow.

The vehicle 1000 may be to navigate a road and/or a track. The vehicle 1000 may be to move in a direction according to the rotation of at least one wheel. For example, the vehicle 1000 may include three-wheeled or four-wheeled cars, construction machinery, two-wheeled cars, motorized devices, bicycles, and/or trains running on tracks.

The vehicle 1000 may include a body having an interior and exterior and a chassis, which is the remaining portion of the vehicle 1000 other than the body and includes mechanical devices desired or required for driving. The exterior of the body may include a front panel, a bonnet, a roof panel, a rear panel, a trunk, and pillars on the boundaries between doors. The chassis of the vehicle 1000 may be to support a power generation device, a power transmission system, a running gear, a steering device, a braking device, a suspension device, a transmission device, a fuel device, and front, rear, left, and right wheels.

The vehicle 1000 may include side window glass 1100, front window glass 1200, side-view mirrors 1300, an instrument cluster 1400, a center fascia 1500, a passenger side dashboard 1600, and a display apparatus 1.

The side window glass 1100 and the front window glass 1200 may be partitioned by pillars arranged therebetween.

The side window glass 1100 may be installed on the side of the vehicle 1000. In one or more embodiments, the side window glass 1100 may be installed on a door of the vehicle 1000. A plurality of pieces of side window glass 1100 may be provided and may be opposite to (e.g., face) each other. In one or more embodiments, the side window glass 1100 may include first side window glass 1110 and second side window glass 1120. The first side window glass 1110 may be arranged adjacent to the instrument cluster 1400. The second side window glass 1120 may be arranged adjacent to the passenger side dashboard 1600.

The pieces of side window glass may be spaced and/or apart (e.g., spaced apart or separated) from each other in a first direction (e.g., x direction). For example, the first side window glass 1110 may be spaced and/or apart (e.g., spaced apart or separated) from the second side window glass 1120 in the x direction or the -x direction. For example, a virtual line L connecting the pieces of side window glass 1100 may extend in the first direction (e.g., x direction). For example, the virtual line L connecting the first side window glass 1110 to the second side window glass 1120 may extend either in the x direction or the -x direction.

The front window glass 1200 may be installed at the front of the vehicle 1000. The front window glass 1200 may be arranged between the pieces of side window glass opposite to (e.g., facing) each other.

The side-view mirror 1300 may be to provide a view of the rear of the vehicle 1000. The side-view mirror 1300 may be installed on the exterior of the body. In one or more embodiments, the side-view mirror 1300 may be provided in plurality. Any one selected from among the side-view mirrors 1300 may be arranged on the outer side of the first side window glass 1110. Another one selected from among the side-view mirrors 1300 may be arranged on the outer side of the second side window glass 1120.

The instrument cluster 1400 may be at the front of the steering wheel. On the instrument cluster 1400, a tachometer, a speedometer, a coolant temperature gauge, a fuel gauge, a turn signal indicator, a high beam indicator, warning lights, a seatbelt warning light, a trip meter, an odometer, an automatic transmission selector indicator, a door ajar warning light, an engine oil warning light, and/or a low fuel warning light may be arranged.

The center fascia 1500 may include a control panel with a plurality of buttons to adjust an audio system, an air conditioning system, and seat heaters. The center fascia 1500 may be on a side of the instrument cluster 1400.

The passenger side dashboard 1600 may be apart from the instrument cluster 1400 with the center fascia 1500 therebetween. In one or more embodiments, the instrument cluster 1400 may correspond to the driver's seat, and the passenger side dashboard 1600 may correspond to the passenger side. In one or more embodiments, the instrument cluster 1400 may be adjacent to the first side window glass 1110, and the passenger side dashboard 1600 may be adjacent to the second side window glass 1120.

The display apparatus 1 may be inside the vehicle 1000. The display apparatus 1 may be arranged between the pieces of side window glass opposite to (e.g., facing) each other. The display apparatus 1 may be to display images. The display apparatus 1 may be arranged on at least any one selected from among the instrument cluster 1400, the center fascia 1500, and the passenger side dashboard 1600.

The display apparatus 1 may include a liquid crystal display apparatus, an electrophoretic display apparatus, an organic light-emitting display apparatus, an inorganic light-emitting display apparatus, a field emission display apparatus, a surface-conduction electron-emitter display apparatus, a quantum dot display apparatus, a plasma display apparatus, a cathode ray display apparatus, and/or the like. Hereinafter, a case where the display apparatus 1 according to one or more embodiments is an organic light-emitting display apparatus may be described in more detail, but display apparatuses of one or more suitable types (kinds) as stated herein may be utilized in one or more embodiments.

Referring to FIG. 2, the display apparatus 1 may be arranged on the instrument cluster 1400. In this case, the instrument cluster 1400 may be to display driving information and/or the like utilizing the display apparatus 1. For example, the instrument cluster 1400 may be implemented in a digital form. The instrument cluster 1400 in the digital form may be to display vehicle information and driving information as images. For example, the needle and gauge of the tachometer and icons of one or more suitable warning lights may be displayed utilizing digital signals.

Light emitted from the display apparatus 1 may travel in a set or specific direction. For example, the light emitted from the display apparatus 1 may travel towards the driver's seat. In one or more embodiments, light emitted from the display apparatus 1 may not travel to the front window glass 1200. In one or more embodiments, the light emitted from the display apparatus 1 may travel to the front window glass 1200 at a relatively small rate. If (e.g., when) the light emitted from the display apparatus 1 travels toward the front window glass 1200, the light emitted from the display apparatus 1 may be reflected by the front window glass 1200 and may reach the driver's seat. Therefore, the driver may recognize the image of the display apparatus 1 formed on the front window glass 1200, which may cause safety problems if (e.g., when) driving. In one or more embodiments, because the vertical viewing angle of the display apparatus 1 arranged in the instrument cluster 1400 is limited, the light emitted from the display apparatus 1 and traveling toward the front window glass 1200 may be significantly or substantially reduced.

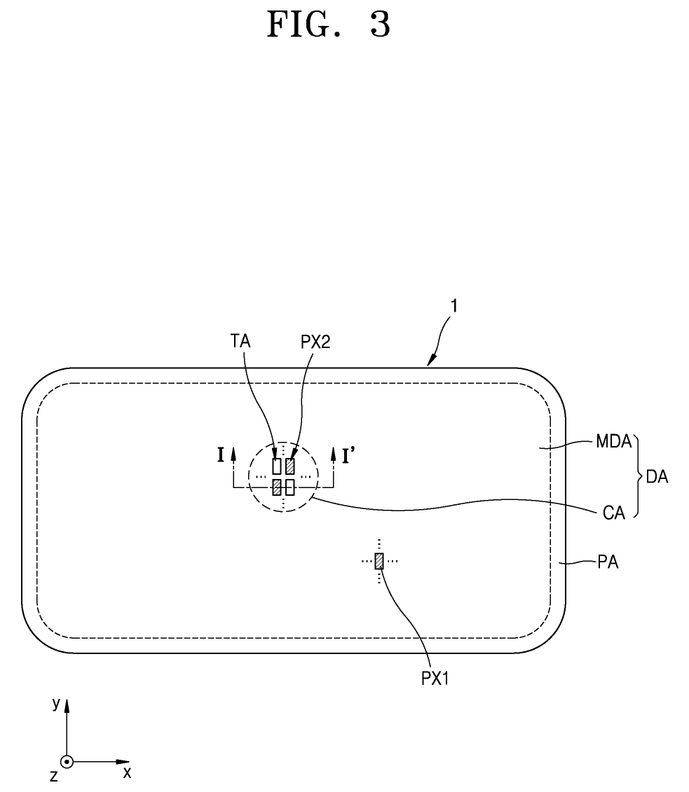

FIG. 3 is a schematic plan view of a display apparatus according to one or more embodiments.

Referring to FIG. 3, the display apparatus 1 may include a display area DA and a peripheral area PA outside the display area DA. In plan view, the display area DA may have an approximately rectangular shape as illustrated in FIG. 1. However, embodiments of the present disclosure are not limited thereto, and the display area DA may have a polygonal (e.g., substantially polygonal) type (kind) shape, such as a triangle (e.g., substantially a triangle), a pentagon (e.g., substantially a pentagon), or a hexagon (e.g., substantially a hexagon), a circular (e.g., substantially circular) type (kind) shape, an elliptical (e.g., substantially elliptical) type (kind) shape, or an atypical type (kind) shape. The corners of the edges of the display area DA may have a rounded (e.g., substantially rounded) shape. The peripheral area PA may be a non-display area where no display elements are placed or arranged. The display area DA may be entirely (e.g., substantially entirely) surrounded by the peripheral area PA.

The display area DA may include a main display area MDA and a component area CA. The main display area MDA may have a shape around (e.g., surrounding) the component area CA. However, embodiments of the present disclosure are not limited thereto, and one or more suitable modifications may be made, such as a part of the component area CA being in contact with the peripheral area PA. For example, the main display area MDA may be at least partially around (e.g., surround) the component area CA.

The display apparatus 1 may be to provide an image utilizing sub-pixels arranged in the display area DA. Each of the sub-pixels may include a display element and sub-pixel circuits electrically connected to the display element. The display element may be an organic light-emitting diode emitting red light, green light, or blue light. The sub-pixels may be arranged in one or more suitable forms, such as a stripe arrangement structure, a PENTILE® arrangement structure (e.g., an RGBG matrix, an RGBG structure, or an RGBG matrix structure), or a mosaic arrangement structure in the x direction and y direction to display images. PENTILE® is a duly registered trademark of Samsung Display Co., Ltd. The sub-pixels may include a plurality of first sub-pixels PX1 arranged in the main display area MDA and a plurality of second sub-pixels PX2 arranged in the component area CA. Each of the plurality of first sub-pixels PX1 and the plurality of second sub-pixels PX2 may be one selected from among a red sub-pixel, a green sub-pixel, and a blue sub-pixel.

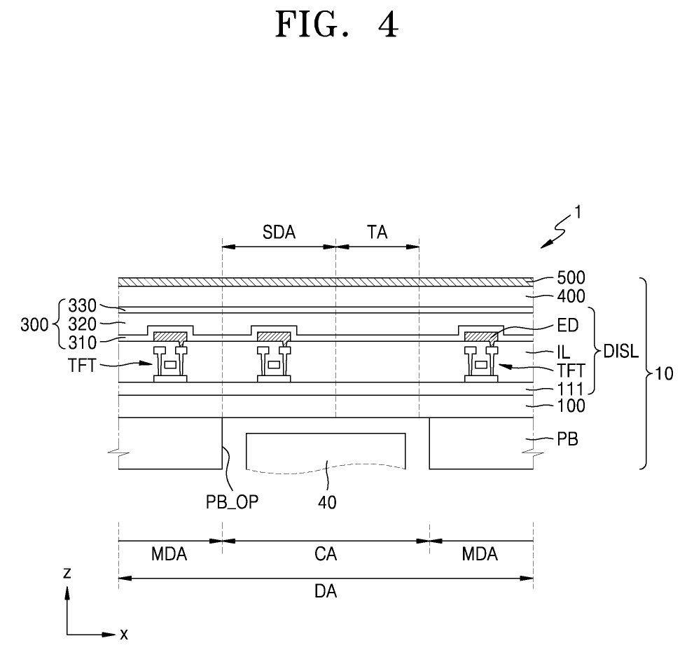

A component 40 (see FIG. 4), which is an electronic element, may be arranged under a display panel 10 (see FIG. 4) corresponding to the component area CA. The component area CA may include a transmission area TA through which light and/or sound output from the component 40 (see FIG. 4) to the outside or traveling from the outside toward the component 40 (see FIG. 4) may be transmitted.

Because the component area CA includes transmission areas TA, the number of second sub-pixels PX2 arranged per unit area in the component area CA may be less than the number of first sub-pixels PX1 arranged per unit area in the main display area MDA. For example, a resolution of the component area CA may be lower than a resolution of the main display area MDA.

The component 40 (see FIG. 4) may be an electronic element using light or sound. For example, the electronic element may be a sensor to measure a distance, such as a proximity sensor, a sensor to recognize a portion (e.g., a fingerprint, an iris, a face, and/or the like.) of a user's body, a small lamp to output light, an illuminance sensor to measures brightness, or an image sensor (e.g., a camera) to capture an image. The electronic element using light may use light of one or more suitable wavelength bands, such as visible light, infrared light, and ultraviolet light. The electronic element using sound may use ultrasound or sound of other frequency bands. In one or more embodiments, the component 40 (see FIG. 4) may be a sensor using infrared light or a camera using infrared light.

If (e.g., when) viewed in a direction (z direction) normal or perpendicular to the upper surface of the display apparatus 1, the component area CA may have a polygonal (e.g., substantially polygonal) shape, such as a triangle (e.g., substantially a triangle), a square (e.g., substantially a square), a pentagon (e.g., substantially a pentagon), or a hexagon (e.g., substantially a hexagon), a circular (e.g., substantially circular) shape, an elliptical (e.g., substantially elliptical) shape, a star (e.g., substantially star) shape, or an atypical shape.

FIG. 3 illustrates that the display area DA includes one component area CA. However, embodiments of the present disclosure are not limited thereto. For example, the component area CA may include a plurality of sub-component areas spaced and/or apart (e.g., spaced apart or separated) from each other. The sizes of the plurality of sub-component areas may be different from each other as needed or desired. If (e.g., when) the component area CA includes a plurality of sub-component areas, the components 40 (see FIG. 4) that have different functions may be arranged to correspond to each of the sub-component areas.

FIG. 4 is a cross-sectional view of the display apparatus taken along the line I-I' of FIG. 3, according to one or more embodiments.

The display apparatus 1 may include the display panel 10 and the component 40 arranged to overlap the display panel 10. A cover window to protect the display panel 10 may be arranged on the display panel 10.

The display area DA of the display panel 10 may include the component area CA and the main display area MDA. A main image may be displayed in the main display area MDA, and an auxiliary image may be displayed in the component area CA. The component 40 may be arranged under the display panel 10 to correspond to the component area CA. For example, if (e.g., when) viewed in a direction (z-axis direction) approximately normal or perpendicular to the display apparatus 1, the component area CA may overlap the component 40.

The display panel 10 may include a substrate 100, a display layer DISL on the substrate 100, an input sensing layer 400, a light control layer 500, and a panel protective member PB arranged under the substrate 100.

The substrate 100 may include glass, metal, and/or a polymer resin. If (e.g., when) the substrate 100 has flexible or bendable characteristics, the substrate 100 may include a polymer resin, such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP). Further, one or more suitable modifications may be feasible, and, for example, the substrate 100 may have a multi-layered structure including two layers including such a polymeric resin and a barrier layer between the layers, wherein the barrier layer includes an inorganic material (e.g., silicon oxide, silicon nitride, silicon oxynitride, and/or the like) between the layers.

The display layer DISL on the substrate 100 may include a sub-pixel circuit including thin-film transistors TFT, a light-emitting element ED that is a display element, and an encapsulation layer 300. In FIG. 4, the display layer DISL includes a buffer layer 111, and the thin-film transistor TFT may be arranged on the buffer layer 111. The light-emitting element ED may be an organic light-emitting diode (OLED). The sub-pixel circuit including the thin-film transistor TFT may be to control light-emission or the degree of light-emission of the light-emitting element ED. In one or more embodiments, a semiconductor layer of the thin-film transistor TFT and an insulating layer IL for insulation (e.g., electrical insulation) between a gate electrode and/or source/drain electrodes may be included in the display layer DISL.

The light-emitting element ED may be located or arranged in the component area CA in addition to the main display area MDA. For example, the component area CA may include sub-display areas SDA and transmission areas TA, and light-emitting elements ED may be arranged in the sub-display areas SDA. The transmission area TA may also be defined as an area in which the light-emitting elements ED are not arranged, in the component area CA. The transmission area TA may be an area through which is transmitted a light/signal emitted from the component 40 arranged to correspond to the component area CA or a light/signal incident on the component 40. The thin-film transistor TFT electrically connected to the light-emitting element ED in the component area CA may be located or arranged in the component area CA, as illustrated in FIG. 4, or may be located or arranged in the main display area MDA and electrically connected to the light-emitting element ED in the component area CA through wiring and/or the like.

Display elements, such as the light-emitting element ED, may be covered by the encapsulation layer 300, as illustrated in FIG. 4. In one or more embodiments, the display elements may also be covered by a sealing substrate. The encapsulation layer 300 may include at least one inorganic encapsulation layer and at least one organic encapsulation layer, as illustrated in FIG. 4. For example, the encapsulation layer 300 may include a first inorganic encapsulation layer 310, a second inorganic encapsulation layer 330, and an organic encapsulation layer 320 therebetween.

The first inorganic encapsulation layer 310 and the second inorganic encapsulation layer 330 may include one or more inorganic insulating (e.g., electrically insulating) materials, such as silicon oxide (e.g., SiOₓ, wherein 0 < x ≤ 2; e.g., SiO₂), silicon nitride (e.g., SiₓN_{y}, wherein 0 < x ≤ 3 and 0 < y ≤ 4; e.g., Si₃N₄), silicon oxynitride (e.g., SiₓON_{y}, wherein 0 < x ≤ 2 and 0 ≤ y ≤ 2; e.g., SiON or Si₂N₂O), aluminum oxide (e.g., AlₓO_{y}, wherein 0 < x ≤ 2 and 0 < y ≤ 3; e.g., Al₂O₃), titanium oxide (e.g., TiOₓ, wherein 0 < x ≤ 2; e.g., TiO₂), tantalum oxide (e.g., TaOₓ, wherein 0 < x ≤ 3; e.g., Ta₂O₅), hafnium oxide (e.g., HfOₓ, wherein 0 < x ≤ 2; e.g., HfO₂), and/or zinc oxide (e.g., ZnOₓ, wherein 0 < x ≤ 2; e.g., ZnO), through chemical vapor deposition (CVD) and/or the like. The organic encapsulation layer 320 may include a polymer-based material. The polymer-based material may include a silicon-based resin, an acryl-based resin (e.g., polymethylmethacrylate, polyacrylic acid, and/or the like), an epoxy resin, polyimide, polyethylene, and/or the like.

Each of the first inorganic encapsulation layer 310, the organic encapsulation layer 320, and the second inorganic encapsulation layer 330 may be integrally formed to cover the main display area MDA and the component area CA.

The input sensing layer 400 may be to obtain coordinate information according to an external input, for example, a touch event. The input sensing layer 400 may include a touch electrode and touch lines connected to the touch electrode. The input sensing layer 400 may be to sense the external input by using a magnetic capacitance method or a mutual capacitance method.

The input sensing layer 400 may be formed on the encapsulation layer 300. In one or more embodiments, the input sensing layer 400 may be arranged on the encapsulation layer 300 through an adhesive layer, such as an optical clear adhesive (OCA), after being separately formed on the touch substrate. In one or more embodiments, the input sensing layer 400 may be directly formed on the encapsulation layer 300. In this case, the adhesive layer may not be arranged between the input sensing layer 400 and the encapsulation layer 300.

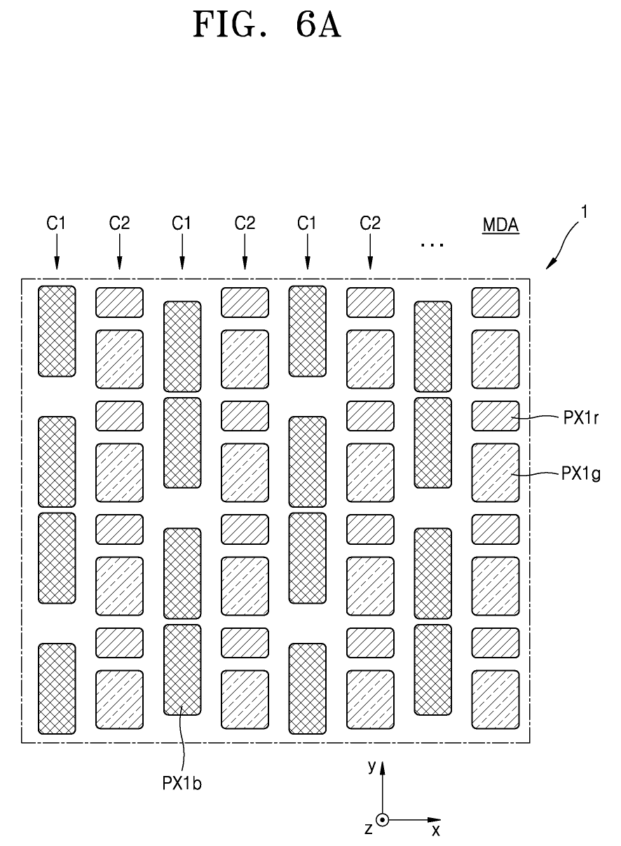

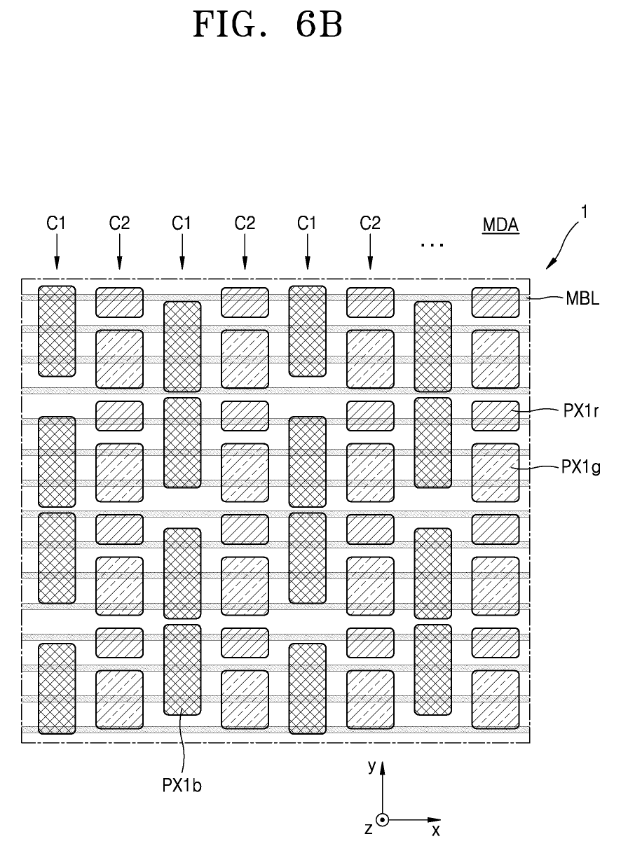

The light control layer 500 may be arranged on the input sensing layer 400. The light control layer 500 may be to control a traveling direction of light emitted from the display layer DISL. For example, a second direction (e.g., y direction) component of the light emitted from the display layer DISL may be at least partially removed by the light control layer 500. As will be described in more detail herein with reference to FIGS. 6A to 8, the light control layer 500 may include a plurality of light-blocking lines. The plurality of light-blocking lines may include a light-blocking material. The plurality of light-blocking lines may extend in the first direction (e.g., x direction) and may be spaced and/or apart (e.g., spaced apart or separated) from each other in the second direction (e.g., y direction).

The cover window may be arranged on an upper portion of the display panel 10, for example, an upper portion of the light control layer 500, to protect the display panel 10. The cover window may be coupled to the light control layer 500 through an adhesive layer, such as an OCA. The cover window may include a glass material and/or a plastic material. The glass material may include ultra-thin glass. The plastic material may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like.

The panel protective member PB may be attached to a lower portion of the substrate 100 and may be to support and protect the substrate 100. The panel protective member PB may have an opening PB_OP corresponding to the component area CA. The panel protective member PB may have the opening PB_OP so that (e.g., such that) light transmittance of the component area CA may be enhanced. The panel protective member PB may include polyethylene terephthalate and/or polyimide.

The area of the component area CA may be greater than the area in which the component 40 is arranged. Thus, the area of the opening PB_OP provided in the panel protective member PB may not coincide with the area of the component area CA. In FIG. 4, at least a part of the component 40 is inserted into the opening PB_OP provided in the panel protective member PB. However, the component 40 may be spaced and/or apart (e.g., spaced apart or separated) from the display panel 10.

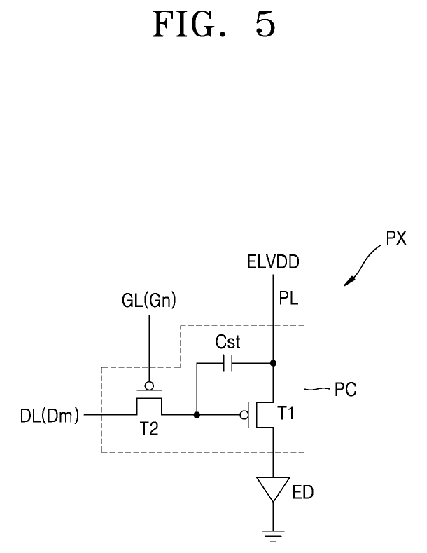

FIG. 5 is a schematic equivalent circuit diagram of a light-emitting diode provided in one sub-pixel and a sub-pixel circuit connected to the light-emitting diode, according to one or more embodiments.

Referring to FIG. 5, in one or more embodiments, a sub-pixel PX may include a sub-pixel circuit PC and a light-emitting element ED electrically connected to the sub-pixel circuit PC. The sub-pixel circuit PC may include a first transistor T1, a second transistor T2, and a capacitor Cst. The sub-pixel circuit PC may be electrically connected to a gate line GL and a data line DL. The first transistor T1 may be a driving transistor, and the second transistor T2 may be a switching transistor. The second transistor T2 may be electrically connected to the gate line GL and the data line DL and may be to transmit a data signal Dm input through the data line DL to the first transistor T1 according to a gate signal Gn input through the gate line GL.

The capacitor Cst may be connected to the second transistor T2 and the driving voltage line PL and may be to store a voltage corresponding to a difference between a voltage received from the second transistor T2 and the driving voltage ELVDD supplied to the driving voltage line PL.

The first transistor T1 may be connected to the driving voltage line PL and the capacitor Cst and may be to control a driving current flowing from the driving voltage line PL to the light-emitting diode ED corresponding to a value of the voltage stored in the capacitor Cst. The light-emitting diode ED may be to emit light having a certain luminance by the driving current.

In one or more embodiments, although the sub-pixel circuit PC is illustrated as including two transistors and one capacitor, embodiments of the present disclosure are not limited thereto. In one or more embodiments, the sub-pixel circuit PC may include three or more transistors and/or two or more capacitors.

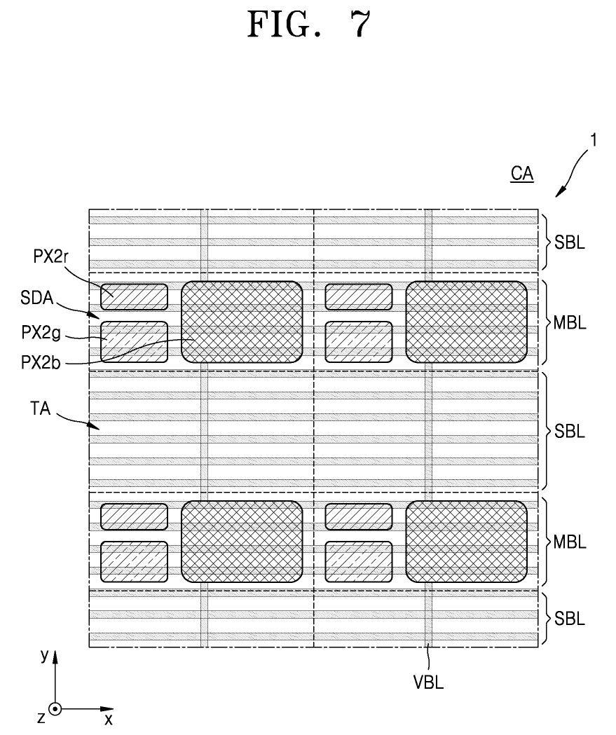

FIGS. 6A and 6B are plan views schematically illustrating a main display area of a display apparatus, according to one or more embodiments. FIG. 7 is a schematic plan view of a component area of a display apparatus, according to one or more embodiments.

First, referring to FIGS. 6A and 6B, a first red sub-pixel PX1r, a first green sub-pixel PX1g, a first blue sub-pixel PX1b, and a main light-blocking line MBL may be arranged in the main display area MDA of the display apparatus 1. The first red sub-pixel PX1r may be to emit light in a red wavelength band in a range of 630 nm to 780 nm, the first green sub-pixel PX1g may be to emit light in a green wavelength band in a range of 495 nm to 570 nm, and the first blue sub-pixel PX1b may be to emit light in a blue wavelength band in a range of 450 nm to 495 nm.

As illustrated in FIG. 6A, each of the first red sub-pixel PX1r, the first green sub-pixel PX1g, and the first blue sub-pixel PX1b may have a rectangular (e.g., substantially rectangular) shape. In the present disclosure, polygons or squares may also include shapes with rounded vertices. However, embodiments of the present disclosure are not limited thereto, and the first red sub-pixel PX1r, the first green sub-pixel PX1g, and the first blue sub-pixel PX1b may have a polygonal (e.g., substantially polygonal) shape, a circular (e.g., substantially circular) shape, and/or the like.

The sizes of the first red sub-pixel PX1r, the first green sub-pixel PX1g, and the first blue sub-pixel PX1b may be defined as the sizes of light emitting regions of corresponding light-emitting elements. For example, the size of the first red sub-pixel PX1r may be an area in which a light-emitting element emitting red light emits light, the size of the first green sub-pixel PX1g may be an area in which a light-emitting element emitting green light emits light, and the size of the first blue sub-pixel PX1b may be an area in which a light-emitting element emitting blue light emits light.

The first red sub-pixel PX1r, the first green sub-pixel PX1g, and the first blue sub-pixel PX1b may be arranged in a matrix form along a row extending in the first direction (e.g., x direction) and a column extending in the second direction (e.g., y direction). In one or more embodiments, a plurality of first blue sub-pixels PX1b may be repeatedly arranged in the second direction (e.g., y direction) to form a first pixel column C1. A plurality of first red sub-pixels PX1r and a plurality of first green sub-pixels PX1g may be alternately arranged in the second direction (e.g., y direction) and may form a second pixel column C2. The first pixel column C1 and the second pixel column C2 may be provided in plural and may be alternately arranged in the first direction (e.g., x direction). However, the arrangement of a plurality of sub-pixels is not limited thereto. For example, the first red sub-pixel PX1r, the first green sub-pixel PX1g, and the first blue sub-pixel PX1b may be arranged in one or more suitable pixel arrangement structures, such as a PENTILE® arrangement structure (e.g., an RGBG matrix, an RGBG structure, or an RGBG matrix structure), a stripe arrangement structure, a mosaic arrangement structure, or a delta arrangement structure.

Referring to FIG. 6B, a plurality of main light-blocking lines MBL may be arranged on the first red sub-pixel PX1r, the first green sub-pixel PX1g, and the first blue sub-pixel PX1b. Each of the plurality of main light-blocking lines MBL may extend in the first direction (e.g., x direction). Each of the plurality of main light-blocking lines MBL may be spaced and/or apart (e.g., spaced apart or separated) from each other in the second direction (e.g., y direction).

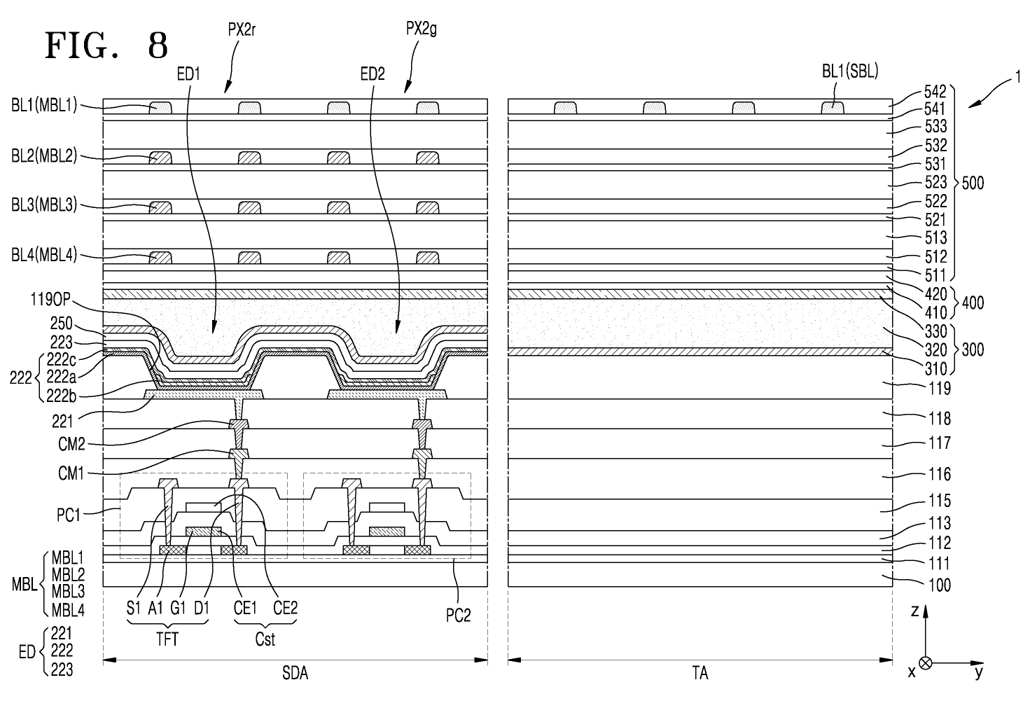

The plurality of main light-blocking lines MBL may include a light-blocking material. The plurality of main light-blocking lines MBL may be to block or absorb light by including the light-blocking material. As will be described in more detail herein with reference to FIG. 8, the plurality of main light-blocking lines MBL may include two or more layers and may include different materials. In one or more embodiments, one or more of the main light-blocking lines MBL in the lower layer may include a black matrix. For example, one or more of the plurality of main light-blocking lines MBL in the lower layer may include at least one selected from among carbon black, black pigment, and black dye. In one or more embodiments, one or more of the plurality of main light-blocking lines MBL in the upper layer may include a light-blocking material having a high infrared transmittance. For example, one or more of the plurality of main light-blocking lines MBL in the upper layer may include at least one selected from among lactam black, perylene black, and aniline black.

The display apparatus 1 according to one or more embodiments may prevent light emitted from the plurality of sub-pixels from traveling in the second direction (e.g., y direction) (or reduce a degree to or occurrence of which light emitted from the plurality of sub-pixels travels in the second direction (e.g., y direction)) as each of the plurality of main light-blocking lines MBL extends in the first direction (e.g., x direction). Accordingly, as described herein in more detail with reference to FIG. 2, the display apparatus according to one or more embodiments may prevent the light emitted from the display apparatus 1 from traveling toward the front window glass 1200 of the vehicle 1000 (or reduce a degree to or occurrence of which the light emitted from the display apparatus 1 travels toward the front window glass 1200 of the vehicle 1000).

Next, referring to FIG. 7, the component area CA may include a sub-display area SDA and a transmission area TA. As described in one or more embodiments, the sub-display area SDA may overlap the component 40 (see FIG. 4) and may be an area in which the sub-pixel including the sub-pixel circuit and the light-emitting element connected thereto is arranged. The transmission area TA may be an area which overlaps with the component 40 (see FIG. 4) and in which no sub-pixels are placed to increase or enhance the transmittance of light directed toward the component 40 (see FIG. 4).

A second red sub-pixel PX2r, a second green sub-pixel PX2g, a second blue sub-pixel PX2b, and the main light-blocking line MBL may be arranged in the sub-display area SDA. The second red sub-pixel PX2r may be to emit light in a red wavelength band in a range of 630 nm to 780 nm, the second green sub-pixel PX2g may be to emit light in a green wavelength band in a range of 495 nm to 570 nm, and the second blue sub-pixel PX2b may be to emit light in a blue wavelength band in a range of 450 nm to 495 nm.

As illustrated in FIG. 7, each of the second red sub-pixel PX2r, the second green sub-pixel PX2g, and the second blue sub-pixel PX2b may have a rectangular (e.g., substantially rectangular) shape. In the present disclosure, polygons or squares may also include shapes with rounded vertices. However, embodiments of the present disclosure are not limited thereto, and the second red sub-pixel PX2r, the second green sub-pixel PX2g, and the second blue sub-pixel PX2b may have a polygonal (e.g., substantially polygonal) shape, a circular (e.g., substantially circular) shape, and/or the like.

The sizes of the second red sub-pixel PX2r, the second green sub-pixel PX2g, and the second blue sub-pixel PX2b may be defined as the sizes of light emitting areas of corresponding light-emitting elements. In one or more embodiments, sizes of the second red sub-pixel PX2r, the second green sub-pixel PX2g, and the second blue sub-pixel PX2b may be different from sizes of the first red sub-pixel PX1r, the first green sub-pixel PX1g, and the first blue sub-pixel PX1b, respectively. For example, the size of the second red sub-pixel PX2r may be larger than the size of the first red sub-pixel PX1r, the size of the second green sub-pixel PX2g may be larger than the size of the first green sub-pixel PX1g, and the size of the second blue sub-pixel PX2b may be larger than the size of the first blue sub-pixel PX1b. However, embodiments of the present disclosure are not limited thereto, and the sizes of the second red sub-pixel PX2r, the second green sub-pixel PX2g, and the second blue sub-pixel PX2b may vary depending on a resolution of the component area CA.

In the sub-display area SDA, the plurality of main light-blocking lines MBL may be arranged on the second red sub-pixel PX2r, the second green sub-pixel PX2g, and the second blue sub-pixel PX2b. Each of the plurality of main light-blocking lines MBL may extend in the first direction (e.g., x direction). Each of the plurality of main light-blocking lines MBL may be spaced and/or apart (e.g., spaced apart or separated) from each other in the second direction (e.g., y direction).

The plurality of main light-blocking lines MBL may include a light-blocking material. In one or more embodiments, the plurality of main light-blocking lines MBL arranged in the sub-display area SDA may have substantially the same structure and substantially the same material as the plurality of main light-blocking lines MBL arranged in the main display area MDA. For example, one or more of the plurality of main light-blocking lines MBL in the lower layer may include at least one selected from among carbon black, black pigment, and black dye, and one or more of the plurality of main light-blocking lines MBL in the upper layer may include at least one selected from among lactam black, perylene black, and aniline black.

In one or more embodiments, a plurality of sub-light-blocking lines SBL may be arranged in the transmission area TA. Each of the plurality of sub-light-blocking lines SBL may extend in the first direction (e.g., x direction). Each of the plurality of sub-light-blocking lines SBL may be spaced and/or apart (e.g., spaced apart or separated) from each other in the second direction (e.g., y direction). As illustrated in FIG. 7, the plurality of sub-light-blocking lines SBL may be arranged parallel (e.g., substantially parallel) to the plurality of main light-blocking lines MBL.

The plurality of sub-light-blocking lines SBL may include a light-blocking material. However, as described in one or more embodiments, because the transmission area TA may be an area in which the sub-pixels are not arranged to increase or enhance the transmittance of light directed to the component 40 (see FIG. 4), the plurality of sub-light-blocking lines SBL arranged in the transmission area TA may include a structure different from a structure of the main light-blocking line MBL. For example, the plurality of sub-light-blocking lines SBL may include a single layer structure.

If (e.g., when) the component 40 (see FIG. 4) is a sensor or a camera using infrared light, the plurality of sub-light-blocking lines SBL may include the light-blocking material having a high infrared light transmittance. The plurality of sub-light-blocking lines SBL may include an organic pigment that may shield light in a visible wavelength band and transmit light in an infrared wavelength band. In one or more embodiments, each of the plurality of sub-light-blocking lines SBL may include at least one selected from among Lactam Black, Perlene Black, and Aniline Black. For example, the plurality of sub-light-blocking lines SBL may include the light-blocking material having a transmittance in a range of about 90 % to about 100 % for light having a wavelength of about 940 nm.

In one or more embodiments, the display apparatus 1 according to one or more embodiments may improve or enhance the efficiency of sensors using infrared light by having sub-light-blocking lines SBL containing the light-blocking material with high infrared light transmittance arranged in the transmission area TA. Furthermore, the display apparatus 1 according to one or more embodiments may be to control the direction of the light emitted from the light-emitting element ED (see FIG. 4) by having the main light-blocking line MBL, which has a multilayer structure of the light-blocking line including a general light-blocking material, such as carbon black, and a light-blocking line including the light-blocking material with a high infrared light transmittance, arranged in the main display area MDA and the sub-display area SDA.

In one or more embodiments, the display apparatus 1 may further include a vertical light-blocking line VBL crossing the main light-blocking line MBL and the sub-light-blocking line SBL. Each of a plurality of vertical light-blocking lines VBL may extend in the second direction (e.g., y direction). Each of the plurality of vertical light-blocking lines VBL may be spaced and/or apart (e.g., spaced apart or separated) from each other in the first direction (e.g., x direction). The plurality of vertical light-blocking lines VBL may be arranged to overlap a signal wiring arranged under the light control layer 500 (see FIG. 4) in plan view. For example, the signal wiring may be a data line configured or arranged to transmit electrical signals (e.g., data signals) to a sub-pixel circuit. However, embodiments of the present disclosure are not limited thereto; the signal wiring may also be configured or arranged to transmit signals to a main pixel circuit electrically connected to the main light-emitting element. If (e.g., when) the signal wiring is composed of a metal layer, it may reflect external light and interfere with the user's view. Accordingly, the display apparatus 1 according to one or more embodiments may further improve or enhance display quality by additionally including the vertical light-blocking line VBL including the light-blocking material.

FIG. 8 is a cross-sectional view schematically illustrating a portion of a display apparatus, according to one or more embodiments. FIG. 8 schematically illustrates a portion of the sub-display area SDA and a portion of the transmission area TA of the display apparatus 1, to describe the light control layer 500 in the sub-display area SDA and the light control layer 500 in the transmission area TA. In this case, a part of the cross-sectional structure of the main display area MDA of the display apparatus 1 that coincides with the cross-sectional structure of the sub-display area SDA may be replaced by the description in the sub-display area SDA.

Referring to FIG. 8, the plurality of sub-pixels may be arranged in the sub-display area SDA, and sub-pixels may not be arranged in the transmission area TA. First, the second red sub-pixel PX2r and the second green sub-pixel PX2g may be arranged in the sub-display area SDA. The second red sub-pixel PX2r may include a first light-emitting diode ED1 and a first sub-pixel circuit PC1 electrically connected to the first light-emitting diode ED1. The second green sub-pixel PX2g may include a second light-emitting diode ED2 and a second sub-pixel circuit PC2 electrically connected to the second light-emitting diode ED2.

A buffer layer 111 may be arranged on the substrate 100. The first sub-pixel circuit PC1 and the second sub-pixel circuit PC2 may be arranged on the buffer layer 111. Each of the first sub-pixel circuit PC1 and the second sub-pixel circuit PC2 may include the thin-film transistor TFT and a storage capacitor Cst.

In one or more embodiments, a lower metal layer may further be arranged under the first sub-pixel circuit PC1 and the second sub-pixel circuit PC2. The lower metal layer may be arranged to overlap the thin-film transistor TFT of each of the first sub-pixel circuit PC1 and the second sub-pixel circuit PC2. For example, the lower metal layer may be arranged between the substrate 100 and the buffer layer 111. The lower metal layer may include a conductive (e.g., electrically conductive) material, such as molybdenum (Mo), aluminum (Al), copper (Cu), or titanium (Ti), and may be formed in a single layer or a multilayer. The lower metal layer may reduce deterioration of the thin-film transistor TFT. In one or more embodiments, the lower metal layer may not be provided.

The thin-film transistor TFT may include a semiconductor layer A1, a gate electrode G1, a source electrode S1, and a drain electrode D1. The semiconductor layer A1 may be arranged on the buffer layer 111. The semiconductor layer A1 may include a silicon-based semiconductor material. The silicon-based semiconductor material may include polysilicon and/or amorphous silicon. In one or more embodiments, the semiconductor layer A1 may include an oxide-based semiconductor material. The oxide-based semiconductor material may include an oxide of at least one material selected from among the group consisting of indium (In), gallium (Ga), tin (Sn), zirconium (Zr), vanadium (V), hafnium (Hf), cadmium (Cd), germanium (Ge), chromium (Cr), Ti, and zinc (Zn). The semiconductor layer A1 may include a channel region, and a source region and a drain region which are doped with impurities.

A first gate insulating layer 112 may be provided to cover the semiconductor layer A1. The first gate insulating layer 112 may include an inorganic insulating (e.g., electrically insulating) material, such as silicon oxide, silicon nitride, and/or silicon oxynitride. The first gate insulating layer 112 may be a single layer or multilayer including the inorganic insulating materials as described in one or more embodiments.

The gate electrode G1 overlapping the semiconductor layer A1 may be arranged on the first gate insulating layer 112. The gate electrode G1 may include Mo, Al, Cu, and/or Ti and may be formed in a single layer or a multilayer. In one or more embodiments, the gate electrode G1 may be a single layer including Mo.

A second gate insulating layer 113 may be arranged on the gate electrode G1. The second gate insulating layer 113 may include an inorganic insulating (e.g., electrically insulating) material, such as silicon oxide, silicon nitride, and/or silicon oxynitride. The second gate insulating layer 113 may be a single layer or multilayer including the inorganic insulating materials as described in one or more embodiments.

An upper capacitor electrode CE2 of the storage capacitor Cst may be arranged on the second gate insulating layer 113. The upper capacitor electrode CE2 of the storage capacitor Cst may overlap the gate electrode G1. The gate electrode G1 may be provided integrally with a lower capacitor electrode CE1 of the storage capacitor Cst. The upper capacitor electrode CE2 of the storage capacitor Cst may include a conductive (e.g., electrically conductive) material, such as Mo, Al, Cu, and/or Ti and may be formed in a single layer or a multilayer.

An interlayer insulating layer 115 may cover the upper capacitor electrode CE2 of the storage capacitor Cst. The interlayer insulating layer 115 may include an inorganic insulating (e.g., electrically insulating) material, such as silicon oxide, silicon nitride, and/or silicon oxynitride. The interlayer insulating layer 115 may be a single layer or multilayer including the inorganic insulating materials as described in one or more embodiments.

The source electrode S1 and the drain electrode D1 of the thin-film transistor TFT may be arranged on the interlayer insulating layer 115. The source electrode S1 and the drain electrode D1 of the thin-film transistor TFT may include a conductive (e.g., electrically conductive) material, such as Mo, Al, Cu, and/or Ti, and may be provided in a single layer or a multilayer. In one or more embodiments, the source electrode S1 and the drain electrode D1 of the thin-film transistor TFT may have a multilayer structure of Ti/Al/Ti.

A first planarization layer 116, a second planarization layer 117, and a third planarization layer 118 may be arranged on the source electrode S1 and the drain electrode D1 of the thin-film transistor TFT. The first planarization layer 116, the second planarization layer 117, and the third planarization layer 118 may each include an organic insulating (e.g., electrically insulating) material and/or an inorganic insulating (e.g., electrically insulating) material and may each be provided in a single layer or a multilayer. The organic insulating material may include a polymer that is generally available, such as benzocyclobutene (BCB), polyimide, hexamethyldisiloxane (HMDSO), polymethylmethacrylate (PMMA), and/or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof. The inorganic insulating material may include silicon oxide, silicon nitride, and/or silicon oxynitride. After forming the first planarization layer 116, the second planarization layer 117, and the third planarization layer 118, chemical mechanical polishing may be performed to provide a flat upper surface. In one or more embodiments, one or more of the first planarization layer 116, the second planarization layer 117, and the third planarization layer 118 may not be provided.

The first light-emitting diode ED1 and the second light-emitting diode ED2 may be arranged on the third planarization layer 118. Each of the first light-emitting diode ED1 and the second light-emitting diode may include a pixel electrode 221, a counter electrode 223, and an intermediate layer 222 between the pixel electrode 221 and the counter electrode 223.

The pixel electrode 221 of each of the first light-emitting diode ED1 and the second light-emitting diode ED2 may be arranged on the third planarization layer 118. The pixel electrode 221 may be electrically connected to the first sub-pixel circuit PC1 of the second sub-pixel circuit PC2 through a first contact electrode CM1 between the first planarization layer 116 and the second planarization layer 117 and a second contact electrode CM2 between the second planarization layer 117 and the third planarization layer 118.

The pixel electrode 221 may include a conductive (e.g., electrically conductive) oxide, such as indium tin oxide (ITO), indium zinc oxide (IZO), zinc oxide (e.g., ZnOₓ, wherein 0 < x ≤ 2; e.g., ZnO), indium oxide (e.g., InOₓ, wherein 0 < x ≤ 2; e.g., In₂O₃), indium gallium oxide (IGO), and/or aluminum zinc oxide (AZO). The pixel electrode 221 may include a reflective film including silver (Ag), magnesium (Mg), Al, platinum (Pt), palladium (Pd), gold (Au), nickel (Ni), neodymium (Nd), iridium (Ir), Cr, or compounds thereof. The pixel electrode 221 may further include a film formed or composed of ITO, IZO, ZnO, and/or In₂O₃ above/under the reflective film as described in one or more embodiments. In one or more embodiments, the pixel electrode 221 may have a multilayer structure of ITO/Ag/ITO.

The bank layer 119 may be arranged on the third planarization layer 118 and may cover an edge of the pixel electrode 221. The bank layer 119 may define a pixel opening 119OP to expose a center area of the pixel electrode 221. The pixel opening 119OP may define an emission area of the light-emitting diode ED.

The bank layer 119 may prevent or reduce the occurrence of an arc at the edge of each pixel electrode 221 by increasing a distance between the edge of the pixel electrode 221 and the counter electrode 223. The bank layer 119 may include an organic insulating (e.g., electrically insulating) material, such as polyimide, polyamide, an acryl resin, BCB, HMDSO, and/or a phenol resin.

An intermediate layer 222 may be arranged on the bank layer 119. The intermediate layer 222 may include an emission layer 222b. The emission layer 222b of the light-emitting diode ED may be arranged to overlap the pixel electrode 221 through the pixel opening 119OP. The emission layer 222b may include a polymer (e.g., a high molecular weight organic material) and/or a low molecular weight organic material which emit a certain color (red, green, or blue) of light. The emission layer 222b may include an inorganic material and/or quantum dots.

The intermediate layer 222 may include a first function layer 222a arranged under the emission layer 222b and/or a second function layer 222c above the emission layer 222b. The first function layer 222a may be a hole transport layer (HTL) having a single layer structure. In one or more embodiments, the first function layer 222a may include a hole injection layer (HIL) and the HTL. The second function layer 222c may include an electron transport layer (ETL) and/or an electron injection layer (EIL). The first function layer 222a and the second function layer 222c may each entirely (e.g., substantially entirely) cover the sub-display area SDA. In one or more embodiments, the first function layer 222a and/or the second function layer 222c may not be provided.

The counter electrode 223 may be arranged on the intermediate layer 222. The counter electrode 223 may include a conductive (e.g., electrically conductive) material having a low work function. For example, the counter electrode 223 may include a (semi-)transparent layer including Ag, Mg, Al, Pt, Pd, Au, Ni, Nd, Ir, Cr, lithium (Li), calcium (Ca), or an alloy thereof. In one or more embodiments, the counter electrode 223 may further include a layer including ITO, IZO, ZnO, and/or In₂O₃ on the (semi-)transparent layer including the materials as described in one or more embodiments. The counter electrode 223 may be integrally formed to cover the sub-display area SDA.

A capping layer 250 may be formed on the counter electrode 223. The capping layer 250 may include lithium fluoride (LiF). In one or more embodiments, the capping layer 250 may include an inorganic insulating (e.g., electrically insulating) material, such as silicon nitride, and/or an organic insulating (e.g., electrically insulating) material. In one or more embodiments, the capping layer 250 may not be provided.

The first light-emitting diode ED1 and the second light-emitting diode ED2 may each be sealed by the encapsulation layer 300. The encapsulation layer 300 may be arranged on the capping layer 250. The encapsulation layer 300 may prevent external moisture and/or foreign materials from infiltrating into the first light-emitting diode ED1 and the second light-emitting diode ED2 (or reduce a degree to or occurrence of which external moisture and/or foreign materials infiltrate into the first light-emitting diode ED1 and the second light-emitting diode ED2).

The encapsulation layer 300 may include at least one inorganic encapsulation layer and at least one organic encapsulation layer. For example, the encapsulation layer 300 may include the first inorganic encapsulation layer 310, the organic encapsulation layer 320, and the second inorganic encapsulation layer 330. The first inorganic encapsulation layer 310 and the second inorganic encapsulation layer 330 may each include an inorganic insulating (e.g., electrically insulating) material, such as silicon oxide, silicon nitride, and/or silicon oxynitride. The first inorganic encapsulation layer 310 and the second inorganic encapsulation layer 330 may each be a single layer or multilayer including the materials as described in one or more embodiments. The organic encapsulation layer 320 may include a polymer-based material. The polymer-based material may include an acrylic resin, an epoxy-based resin, polyimide, polyethylene, and/or the like. In one or more embodiments, the organic encapsulation layer 320 may include acrylate.

The input sensing layer 400 may be arranged on the encapsulation layer 300. The input sensing layer 400 may include a first touch electrode, a first touch insulating layer 410, a second touch electrode, and a second touch insulating layer 420. The first touch electrode and the second touch electrode may serve as sensors to detect a user's touch input. The first touch electrode and the second touch electrode may include a metal layer or a transparent (e.g., substantially transparent) conductive (e.g., electrically conductive) layer. The metal layer may include molybdenum (Mo), silver (Ag), titanium (Ti), copper (Cu), aluminum (Al), and alloys thereof. The transparent conductive layer may include transparent (e.g., substantially transparent) conductive (e.g., electrically conductive) oxides, such as indium tin oxide (ITO), indium zinc oxide (IZO), zinc oxide (e.g., ZnOₓ, wherein 0 < x ≤ 2; e.g., ZnO), and indium tin zinc oxide (ITZO), conductive (e.g., electrically conductive) polymers, such as poly(3,4-ethylenedioxythiophene) (PEDOT), metal nanowires, carbon nanotubes, graphene, and/or the like.

Each of the first touch insulating layer 410 and the second touch insulating layer 420 may include an inorganic material and/or an organic material. If (e.g., when) the first touch insulating layer 410 and the second touch insulating layer 420 are provided as an inorganic material, the first touch insulating layer 410 and the second touch insulating layer 420 may include at least one material selected from among the group including silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. If (e.g., when) the first touch insulating layer 410 and the second touch insulating layer 420 are formed or composed of an organic material, the first touch insulating layer 410 and the second touch insulating layer 420 may include at least one material selected from among the group including an acrylic resin, a methacrylic resin, a polyisoprene, a vinyl resin, an epoxy resin, a urethane resin, a cellulose resin, and a perylene resin.

The light control layer 500 may be arranged on the input sensing layer 400. As described in one or more embodiments, the light control layer 500 may include the main light-blocking line MBL arranged in the sub-display area SDA and the main display area MDA and including a multi-layer structure, and the sub-light-blocking line SBL arranged in the transmission area TA and including a single-layer structure. The light control layer 500 may include a plurality of light-blocking layers (such as BL1, BL2, BL3, and BL4), a plurality of clad layers (such as 511, 521, 531, and 541), a plurality of light transmitting layers (such as 512, 522, 532, and 542), and a plurality of interlayer insulating (e.g., electrically insulating) layers (such as 513, 523, and 533).

A first clad layer 511 may be arranged on the input sensing layer 400. The first clad layer 511 may be arranged on the second touch insulating layer 420 to cover the entire (e.g., substantially entire) surface of the display area DA (see FIG. 4). The first clad layer 511 may include an inorganic insulating (e.g., electrically insulating) material, such as silicon oxide, silicon nitride, and/or silicon oxynitride.

A fourth light-blocking layer BL4 may be arranged on the first clad layer 511. The fourth light-blocking layer BL4 may include a plurality of fourth light-blocking lines MBL4 arranged in the sub-display area SDA. The plurality of fourth light-blocking lines MBL4 may be included in the main light-blocking line MBL as described in one or more embodiments. The plurality of fourth light-blocking lines MBL4 may extend in the first direction (e.g., x direction) and may be spaced and/or apart (e.g., spaced apart or separated) from each other in the second direction (e.g., y direction). The plurality of fourth light-blocking lines MBL4 may be arranged in the sub-display area SDA and the main display area MDA, but may not be arranged in the transmission area TA.

The plurality of fourth light-blocking lines MBL4 may include a light-blocking material. The plurality of fourth light-blocking lines MBL4 may include a black matrix. For example, the plurality of fourth light-blocking lines MBL4 may include at least one selected from among carbon black, black pigment, and black dye.

A first light transmitting layer 512 may be arranged on the plurality of fourth light-blocking lines MBL4. The first light transmitting layer 512 may fill a region between the plurality of fourth light-blocking lines MBL4 arranged to be spaced and/or apart (e.g., spaced apart or separated) from each other and may cover upper surfaces of the plurality of fourth light-blocking lines MBL4. The first light transmitting layer 512 may include a transparent (e.g., substantially transparent) organic material capable of transmitting light. For example, the first light transmitting layer 512 may include an organic material, such as an acrylic resin, an epoxy resin, a phenolic resin, a polyamide resin, and a polyimide resin. In one or more embodiments, the first light transmitting layer 512 may include an inorganic material capable of transmitting light. For example, the first light transmitting layer 512 may include an inorganic material, such as silicon nitride, silicon oxynitride, silicon oxide, titanium oxide, and aluminum oxide.

A first interlayer insulating layer 513 may be arranged on the first light transmitting layer 512 to widen an interval between the fourth light-blocking layer BL4 and the third light-blocking layer BL3. The first interlayer insulating layer 513 may include an organic insulating (e.g., electrically insulating) material and/or an inorganic insulating (e.g., electrically insulating) material. The organic insulating material may include a polymer that is generally available, such as benzocyclobutene (BCB), polyimide, hexamethyldisiloxane (HMDSO), polymethylmethacrylate (PMMA), and/or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof. The inorganic insulating material may include silicon oxide, silicon nitride, and/or silicon oxynitride.

A second clad layer 521 may be arranged on the first interlayer insulating layer 513. The second clad layer 521 may be arranged to cover the entire (e.g., substantially entire) surface of the display area DA (see FIG. 4). The second clad layer 521 may include substantially the same material as the first clad layer 511.

A third light-blocking layer BL3 may be arranged on the second clad layer 521. The third light-blocking layer BL3 may include a plurality of third light-blocking lines MBL3 arranged in the sub-display area SDA. The plurality of third light-blocking lines MBL3 may be included in the main light-blocking line MBL as described in one or more embodiments. The plurality of third light-blocking lines MBL3 may extend in the first direction (e.g., x direction) and may be spaced and/or apart (e.g., spaced apart or separated) from each other in the second direction (e.g., y direction). The plurality of third light-blocking lines MBL3 may be arranged in the sub-display area SDA and the main display area MDA, but may not be arranged in the transmission area TA.

The plurality of third light-blocking lines MBL3 may include the light-blocking material. The plurality of third light-blocking lines MBL3 may include the black matrix. For example, the plurality of third light-blocking lines MBL3 may include at least one selected from among carbon black, black pigment, and black dye.

A second light transmitting layer 522 may be arranged on the plurality of third light-blocking lines MBL3. The second light transmitting layer 522 may fill a region between the plurality of third light-blocking lines MBL3 arranged to be spaced and/or apart (e.g., spaced apart or separated) from each other and may cover upper surfaces of the plurality of third light-blocking lines MBL3. The second light transmitting layer 522 may include substantially the same material as the first light transmitting layer 512. A second interlayer insulating layer 523 may be arranged on the second light transmitting layer 522 to widen an interval between the third light-blocking layer BL3 and the second light-blocking layer BL2. The second interlayer insulating layer 523 may include an organic insulating (e.g., electrically insulating) material and/or an inorganic insulating (e.g., electrically insulating) material and may include substantially the same material as the first interlayer insulating layer 513.

A third clad layer 531 may be arranged on the second interlayer insulating layer 523. The third clad layer 531 may be arranged to cover the entire (e.g., substantially entire) surface of the display area DA (see FIG. 4). The third clad layer 531 may include substantially the same material as the first clad layer 511.

A second light-blocking layer BL2 may be arranged on the third clad layer 531. The second light-blocking layer BL2 may include a plurality of second light-blocking lines MBL2 arranged in the sub-display area SDA. The plurality of second light-blocking lines MBL2 may be included in the main light-blocking line MBL as described in one or more embodiments. The plurality of second light-blocking lines MBL2 may extend in the first direction (e.g., x direction) and may be spaced and/or apart (e.g., spaced apart or separated) from each other in the second direction (e.g., y direction). The plurality of second light-blocking lines MBL2 may be arranged in the sub-display area SDA and the main display area MDA, but may not be arranged in the transmission area TA.

The plurality of second light-blocking lines MBL2 may include the light-blocking material. The plurality of second light-blocking lines MBL2 may include the black matrix. For example, the plurality of second light-blocking lines MBL2 may include at least one selected from among carbon black, black pigment, and black dye.

A third light transmitting layer 532 may be arranged on the plurality of second light-blocking lines MBL2. The third light transmitting layer 532 may fill a region between the plurality of second light-blocking lines MBL2 arranged to be spaced and/or apart (e.g., spaced apart or separated) from each other and may cover upper surfaces of the plurality of second light-blocking lines MBL2. The third light transmitting layer 532 may include substantially the same material as the first light transmitting layer 512. A third interlayer insulating layer 533 may be arranged on the third light transmitting layer 532 to widen an interval between the second light-blocking layer BL2 and the first light-blocking layer BL1. The third interlayer insulating layer 533 may include an organic insulating (e.g., electrically insulating) material and/or an inorganic insulating (e.g., electrically insulating) material and may include substantially the same material as the first interlayer insulating layer 513.

A fourth clad layer 541 may be arranged on the third interlayer insulating layer 533. The fourth clad layer 541 may be arranged to cover the entire (e.g., substantially entire) surface of the display area DA (see FIG. 4). The fourth clad layer 541 may include substantially the same material as the first clad layer 511.

The first light-blocking layer BL1 may be arranged on the fourth clad layer 541. The first light-blocking layer BL1 may include a plurality of first light-blocking lines MBL1 arranged in the sub-display area SDA. The plurality of first light-blocking lines MBL1 may be included in the main light-blocking line MBL as described in one or more embodiments. The plurality of first light-blocking lines MBL1 may extend in the first direction (e.g., x direction) and may be spaced and/or apart (e.g., spaced apart or separated) from each other in the second direction (e.g., y direction). A plurality of first light-blocking lines MBL1 may be arranged in the sub-display area SDA and the main display area MDA.

In one or more embodiments, the first light-blocking layer BL1 may further include a plurality of sub-light-blocking lines SBL arranged in the transmission area TA. The plurality of sub-light-blocking lines SBL may be arranged on substantially the same layer as the plurality of first light-blocking lines MBL1 and may include substantially the same material as the plurality of first light-blocking lines MBL1. The plurality of sub-light-blocking lines SBL may extend in the first direction (e.g., x direction) and may be spaced and/or apart (e.g., spaced apart or separated) from each other in the second direction (e.g., y direction).

The plurality of first light-blocking lines MBL1 and the plurality of sub-light-blocking lines SBL may include substantially the same light-blocking material. In one or more embodiments, the plurality of the first light-blocking lines MBL1 and the plurality of sub-light-blocking lines SBL may include a light-blocking material having a high infrared light transmittance. The infrared light transmittance of the plurality of first light-blocking lines MBL1 and the plurality of sub-light-blocking lines SBL may be higher than he infrared light transmittance of the plurality of second to fourth light-blocking lines MBL2, MBL3, and MBL4.

The plurality of the first light-blocking lines MBL and the plurality of sub-light-blocking lines SBL may include an organic pigment capable of blocking light in a visible wavelength band and transmitting light in an infrared wavelength band. For example, the plurality of first light-blocking lines MBL1 and the plurality of sub-light-blocking lines SBL may include at least one selected from among Lactam Black, Perylene Black, and Aniline Black. The plurality of the first light-blocking lines MBL1 and the plurality of sub-light-blocking lines SBL may include the light-blocking material having a transmittance in a range of about 90 % to about 100 % for light having a wavelength of about 940 nm.

In one or more embodiments, the first to fourth light-blocking lines MBL1, MBL2, MBL3, and MBL4 may be arranged to overlap each other in plan view. For example, the main light-blocking line MBL including the first to fourth light-blocking lines MBL1, MBL2, MBL3, and MBL4 may have a multi-layered structure, but may look like a single-layered structure in plan view.

A fourth light transmitting layer 542 may be arranged on the plurality of first light-blocking lines MBL1 and the plurality of sub-light-blocking lines SBL. The fourth light transmitting layer 542 may fill a region between the plurality of first light-blocking lines MBL1 arranged to be spaced and/or apart (e.g., spaced apart or separated) from each other and may cover upper surfaces of the plurality of first light-blocking lines MBL1. In one or more embodiments, the fourth light transmitting layer 542 may fill a region between the plurality of sub-light-blocking lines SBL arranged to be spaced and/or apart (e.g., spaced apart or separated) from each other and may cover upper surfaces of the plurality of sub-light-blocking lines SBL. The fourth light transmitting layer 542 may include substantially the same material as the first light transmitting layer 512.

In one or more embodiments, the structure of the light control layer 500 in the sub-display area SDA may be substantially the same as the structure of the light control layer 500 in the main display area MDA (see FIG. 4). For example, the light control layer 500 arranged in the main display area MDA may include the first to fourth light-blocking layers BL1, BL2, BL3, and BL4. The light control layer 500 arranged in the main display area MDA may include the plurality of first to fourth light-blocking lines MBL1, MBL2, MBL3, and MBL4.

Accordingly, as the display apparatus 1 according to one or more embodiments has the second to fourth light-blocking lines MBL2, MBL3, and MBL4 containing a general light blocking material, such as carbon black, arranged in the main display area MDA and the sub-display area SDA, the driver's visual field interference may be reduced by controlling the traveling direction of light emitted from the light-emitting element ED. Furthermore, the display apparatus 1 according to one or more embodiments may improve or enhance the efficiency of sensors using infrared light and improve or optimize the position of sensors for driver monitors by having sub-light-blocking lines SBL containing high infrared light transmittance, such as lactam black, arranged in the transmission area TA.

In contrast, in one or more embodiments, the first to fourth light-blocking lines MBL1, MBL2, MBL3, and MBL4 may include substantially the same light-blocking material. For example, all of the first to fourth light-blocking lines MBL1, MBL2, MBL3, and MBL4 may include the light-blocking material having the high infrared light transmittance. All of the first to fourth light-blocking lines MBL1, MBL2, MBL3, and MBL4 may include at least one selected from among Lactam Black, Perylene Black, and Aniline Black.

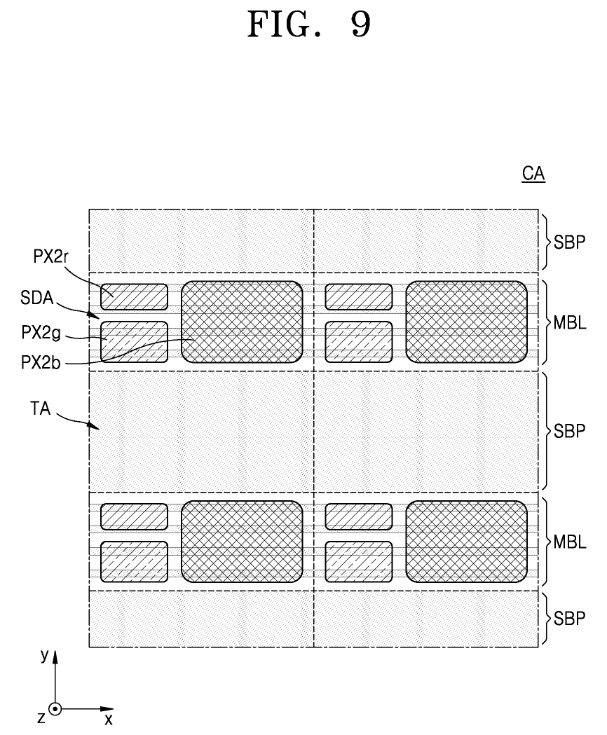

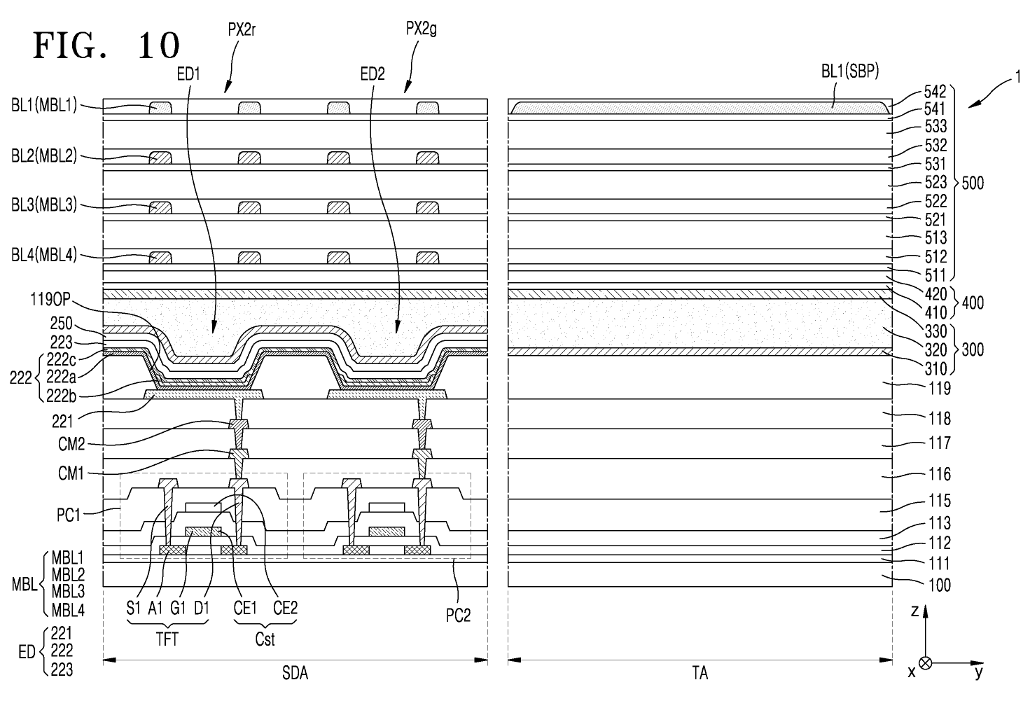

FIG. 9 is a schematic plan view of a component area of a display apparatus, according to one or more embodiments. FIG. 10 is a cross-sectional view schematically illustrating a portion of a display apparatus, according to one or more embodiments. Referring to FIGS. 9 and 10, except for the characteristics of the transmission area TA, other characteristics may each independently be substantially the same as those described in FIGS. 6A to 8. The same reference numerals among the elements of FIGS. 9 and FIG. 10 may each independently be substantially the same as described in one or more embodiments with reference to FIGS. 6A to 8, and hereinafter, only differences will be mainly or predominantly described.

Referring to FIGS. 9 and 10, the component area CA may include a sub-display area SDA and a transmission area TA. The sub-display area SDA may be an area which overlaps the component 40 (see FIG. 4) and in which the plurality of sub-pixels are arranged, and the transmission area TA may be an area which overlaps the component 40 (see FIG. 4) and in which the plurality of sub-pixels are not arranged.

As described in one or more embodiments, a plurality of main light-blocking lines MBL may be arranged in the sub-display area SDA. The plurality of main light-blocking lines MBL may have the multilayer structure. For example, the main light-blocking line MBL may include the first light-blocking line MBL1 of the first light-blocking layer BL1, the second light-blocking line MBL2 of the second light-blocking layer BL2, the third light-blocking line MBL3 of the third light-blocking layer BL3, and the fourth light-blocking line MBL4 of the fourth light-blocking layer BL4.

In one or more embodiments, the infrared light transmittance of the plurality of first light-blocking lines MBL1 may be higher than the infrared light transmittance of the plurality of second to fourth light-blocking lines MBL2, MBL3, and MBL4. For example, the plurality of second to fourth light-blocking lines MBL2, MBL3, and MBL4 may include at least one selected from among carbon black, black pigment, and black dye, and the plurality of first light-blocking lines MBL1 may include at least one selected from among lactam black, perylene black, and aniline black.

A sub-light-blocking pattern SBP may be arranged in the transmission area TA. The sub-light-blocking pattern SBP may be integrally formed to entirely (e.g., substantially entirely) cover the transmission area TA. For example, a planar area of the sub-light-blocking pattern SBP may be substantially the same as a planar area of the transmission area TA. For example, the sub-light-blocking pattern SBP may be formed to cover an upper portion of an area in which sub-pixels are not arranged in the component area CA.

The sub-light-blocking pattern SBP may be included in the first light-blocking layer BL1. For example, the first light-blocking layer BL1 may include the plurality of first light-blocking lines MBL1 in the sub-display area SDA and may include the sub-light-blocking pattern SBP in the transmission area TA. The sub-light-blocking pattern SBP may be arranged on substantially the same layer as the plurality of first light-blocking lines MBL1 and may include substantially the same material as the plurality of first light-blocking lines MBL1. For example, the sub-light-blocking pattern SBP may include the organic pigment capable of blocking light in the visible wavelength band and transmitting light in the infrared wavelength band. For example, the sub-light-blocking pattern SBP may include at least one selected from among lactam black, perylene black, and aniline black. The plurality of the first light-blocking lines MBL1 and the sub-light-blocking pattern SBP may include the light-blocking material having a transmittance in a range of about 90 % to about 100 % for light having a wavelength of about 940 nm.

Accordingly, as the display apparatus 1 according to one or more embodiments has the second to fourth light-blocking lines MBL2, MBL3, and MBL4 containing a general light blocking material, such as carbon black, arranged in the main display area MDA and the sub-display area SDA, the driver's visual field interference may be reduced by controlling the traveling direction of light emitted from the light-emitting element ED. Furthermore, the display apparatus 1 according to one or more embodiments may improve or enhance the efficiency of sensors using infrared light and improve or optimize the position of sensors for driver monitors by having a sub-light-blocking pattern SBP containing a light-blocking material with high infrared light transmittance, such as lactam black, arranged in the transmission area TA.

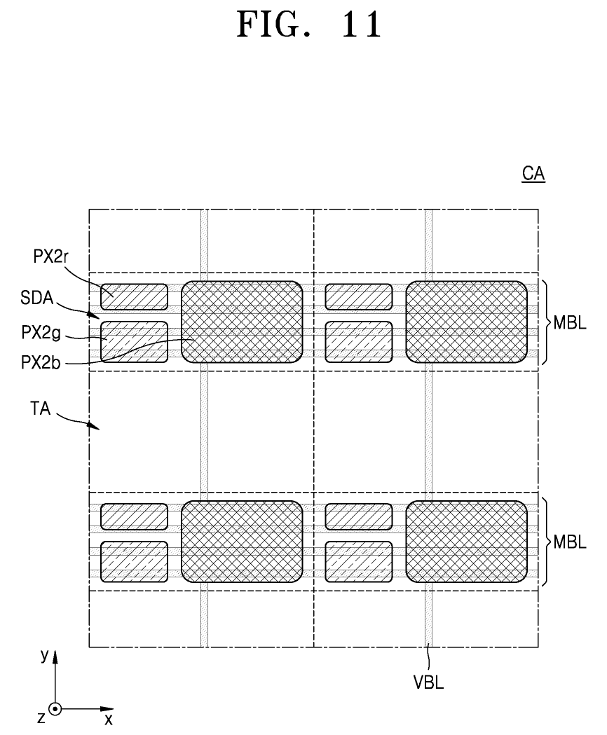

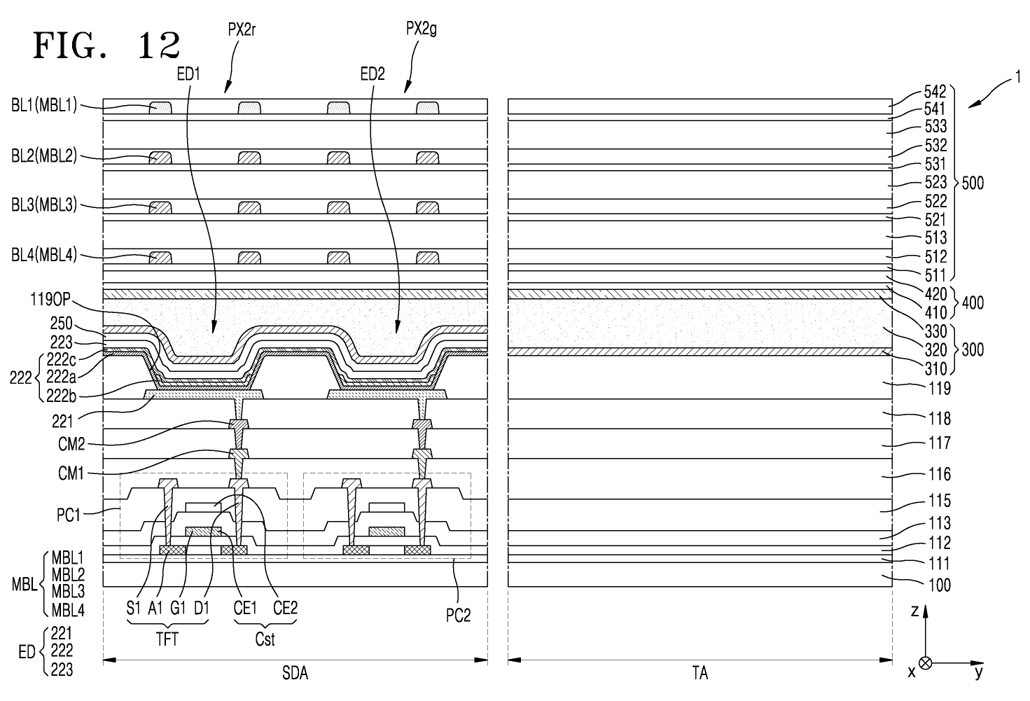

FIG. 11 is a schematic plan view of a component area of a display apparatus, according to one or more embodiments. FIG. 12 is a cross-sectional view schematically illustrating a portion of a display apparatus, according to one or more embodiments. Referring to FIGS. 11 and 12, except for the characteristics of the transmission area TA, other characteristics may each independently be substantially the same as those described in FIGS. 6A to 8. The same reference numerals among the elements of FIGS. 11 and FIG. 12 may each independently be substantially the same as described in one or more embodiments with reference to FIGS. 6A to 8, and hereinafter, only differences will be mainly or predominantly described.

Referring to FIGS. 11 and 12, the component area CA may include a sub-display area SDA and a transmission area TA. The sub-display area SDA may be an area which overlaps the component 40 (see FIG. 4) and in which the plurality of sub-pixels are arranged, and the transmission area TA may be an area which overlaps the component 40 (see FIG. 4) and in which the plurality of sub-pixels are not arranged.

As described in one or more embodiments, a plurality of main light-blocking lines MBL may be arranged in the sub-display area SDA. The plurality of main light-blocking lines MBL may have the multilayer structure. For example, the main light-blocking line MBL may include the first light-blocking line MBL1 of the first light-blocking layer BL1, the second light-blocking line MBL2 of the second light-blocking layer BL2, the third light-blocking line MBL3 of the third light-blocking layer BL3, and the fourth light-blocking line MBL4 of the fourth light-blocking layer BL4.

In one or more embodiments, the infrared light transmittance of the plurality of first light-blocking lines MBL1 may be higher than the infrared light transmittance of the plurality of second to fourth light-blocking lines MBL2, MBL3, and MBL4. For example, the plurality of second to fourth light-blocking lines MBL2, MBL3, and MBL4 may include at least one selected from among carbon black, black pigment, and black dye, and the plurality of first light-blocking lines MBL1 may include at least one selected from among lactam black, perylene black, and aniline black.

In one or more embodiments, the sub-light-blocking line SBL (see FIG. 7) and the sub-light-blocking pattern SBP (see FIG. 9) may not be arranged in the transmission area TA. The plurality of light-blocking layers BL1, BL2, BL3, and BL4 of the light control layer 500 may be arranged only in the sub-display area SDA and the main display area MDA (see FIG. 6A) and may not be arranged in the transmission area TA. In the transmission area TA, the light control layer 500 may include only the plurality of clad layers 511, 521, 531, and 541, the plurality of light transmitting layers 512, 522, 532, and 542, and the plurality of interlayer insulating layers 513, 523, and 533.

As the display apparatus 1 according to one or more embodiments has the second to fourth light-blocking lines MBL2, MBL3, and MBL4 containing a general light blocking material, such as carbon black, arranged in the main display area MDA and the sub-display area SDA, the driver's visual field interference may be reduced by controlling the traveling direction of light emitted from the light-emitting element ED.

In contrast, because the plurality of the light-emitting elements ED are not arranged in the transmission area TA, there may be no need or desire to control the direction of progress of the emitted light in the transmission area TA, so the light-blocking line or light-blocking pattern containing the light-blocking material may not be arranged on the transmission area TA. However, in consideration of the light incident in the lateral direction, the plurality of first light-blocking lines MBL1 arranged at the top of the light-blocking layers of the sub-display area SDA may include the light-blocking material having the high infrared light transmittance. The display apparatus 1 according to one or more embodiments may further improve or enhance the efficiency of a sensor as the light-blocking material is not arranged in the transmission area TA.

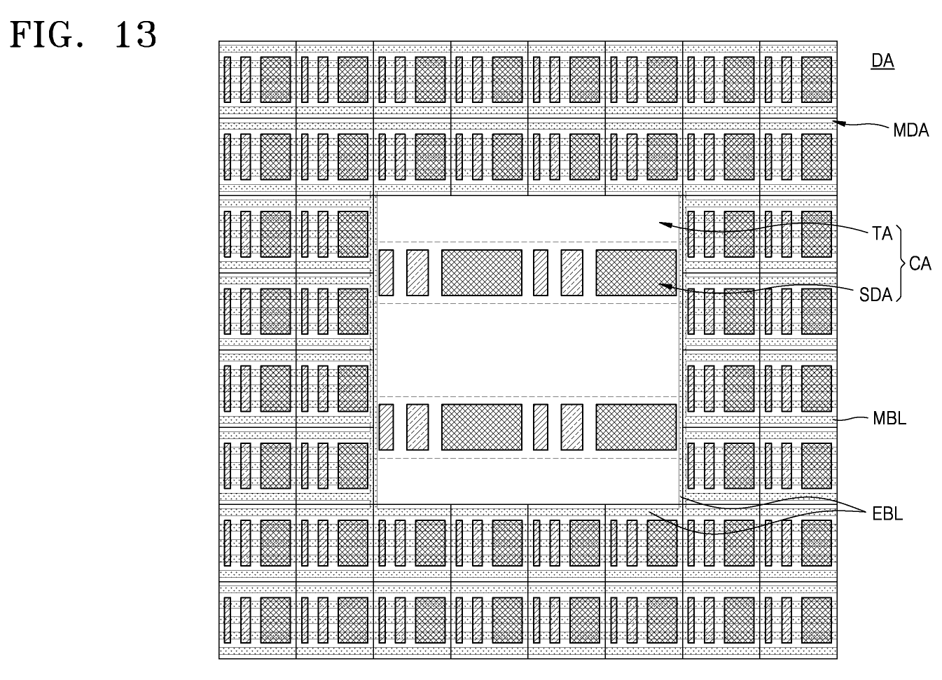

FIG. 13 is a plan view schematically illustrating a display area of a display apparatus according to one or more embodiments. Referring to FIG. 13, except for the characteristics of the component area CA, other characteristics may each independently be substantially the same as those described in FIGS. 6A to 8. The same reference numerals among the elements of FIG. 13 may each independently be substantially the same as described in one or more embodiments with reference to FIGS. 6A to 8, and hereinafter, only differences will be mainly or predominantly described.

Referring to FIG. 13, the display area DA may include a main display area MDA and a component area CA, and the component area CA may include a sub-display area SDA and a transmission area TA. The main display area MDA may be at least partially around (e.g., surround) the component area CA.

The plurality of main light-blocking lines MBL may be arranged on the main display area MDA. Each of the plurality of main light-blocking lines MBL may extend in the first direction (e.g., x direction) and may be spaced and/or apart (e.g., spaced apart or separated) from each other in the second direction (e.g., y direction). The plurality of main light-blocking lines MBL may include the light-blocking material, but may include a multilayer structure. For example, the main light-blocking lines MBL may include first to fourth light-blocking lines MBL1, MBL2, MBL3, and MBL4 (see FIG. 8).

In one or more embodiments, the light-blocking line or the light-blocking pattern including the light-blocking material may not be arranged in the component area CA. The plurality of light-blocking layers BL1, BL2, BL3, and BL4 (see FIG. 8) of the light control layer 500 (see FIG. 8) may be arranged only in the main display area MDA and may not be arranged in the component area CA. In the component area CA, the light control layer 500 (see FIG. 8) may include only the plurality of clad layers 511, 521, 531, and 541 (see FIG. 8), the plurality of light transmitting layers 512, 522, 532, and 542 (see FIG. 8), and the plurality of interlayer insulating layers 513, 523, and 533 (see FIG. 8).

As the display apparatus 1 according to one or more embodiments has the plurality of main light-blocking lines MBL including the light-blocking material arranged in the main display area MDA, the driver's visual field interference may be reduced by controlling the traveling direction of light emitted from the light-emitting element ED (see FIG. 8).

In contrast, the sensor or the camera using infrared light may be arranged under the component area CA, so the higher the light transmittance of the component area CA, the greater the amount of light received by the sensor and the higher the sensing power. Accordingly, the display apparatus 1 according to one or more embodiments may further improve or enhance the efficiency of the sensor by not having the light-blocking line or the light-blocking pattern including the light-blocking material arranged on the component area CA.

In one or more embodiments, an edge light-blocking line EBL may further be arranged at an edge of the component area CA. The edge light-blocking line EBL may be arranged on the boundary between the component area CA and the main display area MDA. The edge light-blocking line EBL may be around (e.g., surround) the component area CA. The edge light-blocking line EBL may be arranged to prevent tearing (or reduce a degree or occurrence of tearing) of ends of the plurality of main light-blocking lines MBL. The edge light-blocking line EBL may be arranged on substantially the same layer as at least one selected from among the first to fourth light-blocking lines MBL1, MBL2, MBL3, and MBL4 (see FIG. 8) included in the main light-blocking line MBL and may include substantially the same material as at least one selected from among the first to fourth light-blocking lines MBL1, MBL2, MBL3, and MBL4 (see FIG. 8).

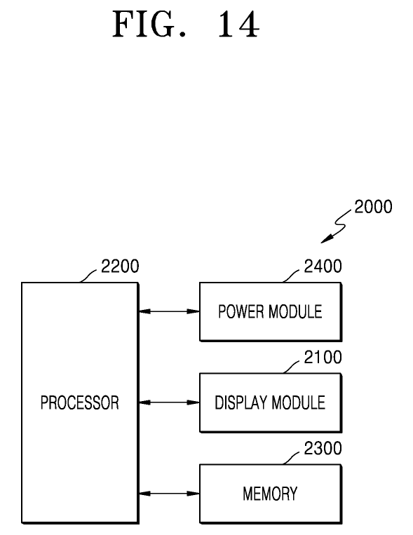

FIG. 14 is a block diagram of an electronic apparatus according to one or more embodiments.

Referring to FIG. 14, an electronic apparatus 2000 according to one or more embodiments may include a display module 2100, a processor 2200, a memory 2300, and a power module 2400.

The electronic apparatus 2000 may be to output one or more suitable information through the display module 2100 within the operating system.

The processor 2200 may include at least one selected from among a central processing unit (CPU), an application processor (AP), a graphics processing unit (GPU), a communication processor (CP), an image signal processor (ISP), and a controller. In one or more embodiments, the processor 2200 may be divided into two or more parts from a functional or structural point of view. For example, the processor 2200 may include a main processor in the form of a first driving chip including a central processing unit and an auxiliary processor in the form of a second driving chip including a controller that receives an image signal from the main processor and processes the image signal to meet the interface specifications of the display module 2100.

The memory 2300 may include at least one selected from a non-volatile memory and a volatile memory. Data information necessary or desired for the operation of the processor 2200 or the display module 2100 may be stored in the memory 2300. If (e.g., when) the processor 2200 executes an application stored in the memory 2300, an image data signal and/or an input control signal may be transmitted to the display module 2100, and the display module 2100 may be to process the provided signal and output image information through the display screen.

The power module 2400 may include a power supply module, such as a power adapter or a battery device, and a power conversion module that converts power supplied by the power supply module to generate power desired or required for the operation of the electronic apparatus 2000. Power conversion by the power conversion module may include, but is not limited to, direct current (DC)-DC conversion, alternating current (AC)-DC conversion, and DC-AC conversion.

At least one selected from among the components of the electronic apparatus 2000 as described in one or more embodiments may be included in the display apparatus according to one or more embodiments. In one or more embodiments, one or more of the individual modules functionally included within one module may be included within the display apparatus, while others may be provided separately from the display apparatus. For example, the display apparatus may include the display module 2100 and the auxiliary processor of the processor 2200, and the main processor of the processor 2200, the memory 2300, and the power module 2400 may be provided in the form of another apparatus within the electronic apparatus 2000 rather than the display apparatus. As another example, the power module 2400 may be provided in the display apparatus and may be to supply power to the processor 2200 and the memory 2300 provided in the electronic apparatus 2000 rather than the display apparatus, but the display apparatus is not limited to the examples.

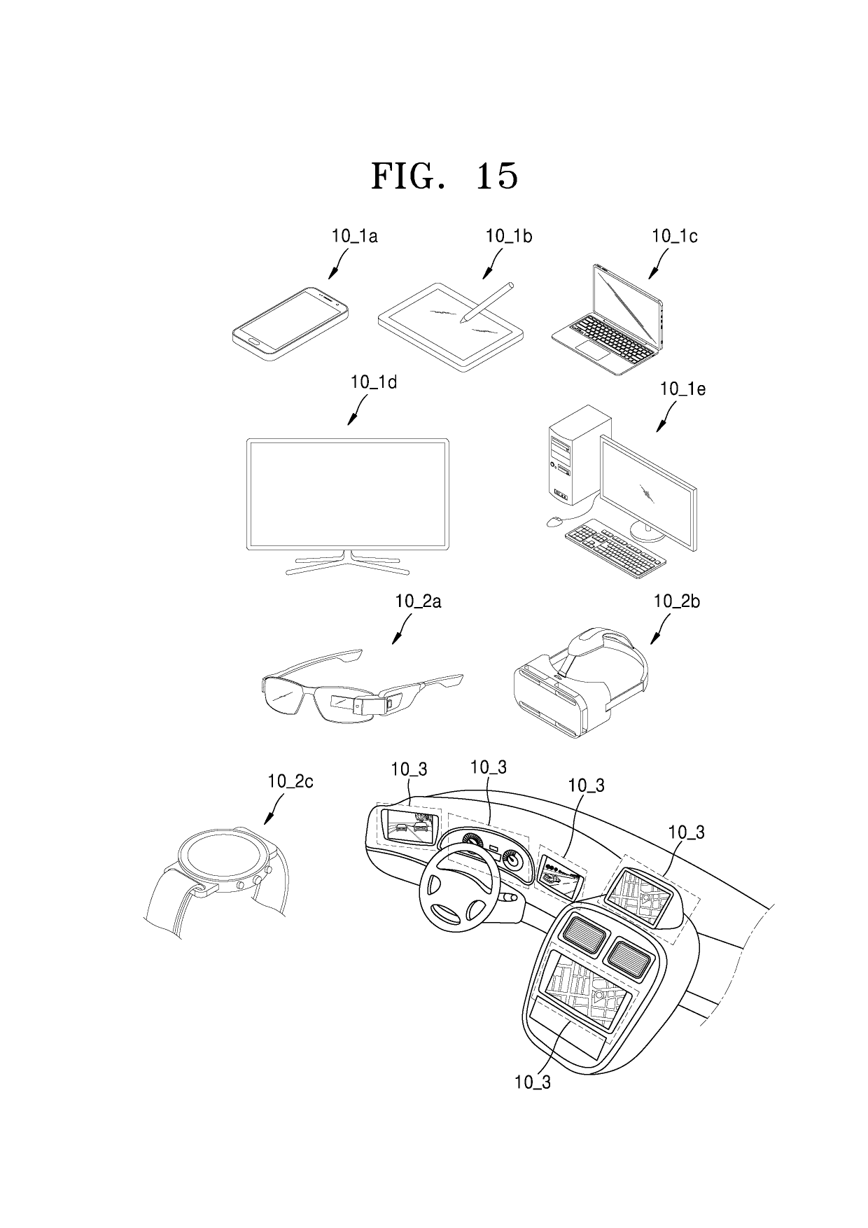

FIG. 15 is a schematic diagram of electronic apparatuses according to one or more embodiments.

The display apparatus according to one or more embodiments may be an apparatus to display a video or a still image and may be applied to one or more suitable electronic apparatuses. Referring to FIG. 15, one or more suitable electronic apparatuses to which the display apparatus according to one or more embodiments is applied may include not only electronic apparatuses for image display, such as a smartphone 10_1a, a tablet PC 10_1b, a laptop 10_1c, a TV 10_1d, and a desk monitor 10_1e, but also wearable electronic devices including display modules, such as smart glasses 10_2a, head mounted display 10_2b, and smart watch 10_2c, a vehicle electronic device 10_3 including display modules, such as a vehicle's instrument panel, a center fascia, a center information display (CID) arranged on a dashboard, and a rearview mirror display. The electronic apparatuses 2000 according to one or more embodiments are not limited to the devices as described herein.

The electronic apparatus of FIG. 15 may include the components as illustrated in FIG. 14. For example, the smartphone 10_1a may include the display module 2100, the processor 2200, the memory 2300, and the power module 2400 as illustrated in FIG. 14. The smartphone 10_1a may further include a communication module and a battery apparatus. Power provided from the battery apparatus may be converted through the power module 2400 and provided to the processor 2200, the memory 2300, and the display module 2100. In one or more embodiments, the display apparatus applied to the smartphone 10_1a may include the display module 2100 and may further include the power module 2400. The processor 2200 and the memory 2300 may be provided in the form of a chip mounted on a mother board, which is an external device, but embodiments of the present disclosure are not limited thereto.

The display apparatus and the electronic apparatus including the display apparatus according to one or more embodiments as described herein may reduce reflection by a window of a vehicle so as not to interfere with a user's field of view and may increase or enhance the efficiency of a sensor for a driver monitor. In one or more embodiments, this is merely an example, and the scope of the present disclosure is not limited thereby.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

While the subject matter of the present disclosure has been described in connection with what is presently considered to be practical example embodiments, it is to be understood that the present disclosure is not limited to the disclosed embodiments, but in one or more embodiments, is intended to cover one or more suitable modifications and equivalent arrangements included within the spirit and scope of the appended claims and equivalents thereof. It therefore will be understood that one or more embodiments described herein are just illustrative but not limitative in all aspects.

What is claimed is:

1. A display apparatus comprising:
a substrate comprising a component area and a main display area at least partially around the component area, the component area comprising a sub-display area and a transmission area;
a display layer comprising a main light-emitting element in the main display area and a sub-light-emitting element in the sub-display area; and
a light control layer on the display layer and comprising a first light-blocking layer and a second light-blocking layer under the first light-blocking layer;
wherein the first light-blocking layer comprises a plurality of first light-blocking lines extending in a first direction, the plurality of first light-blocking lines comprising a first light-blocking material,
wherein the second light-blocking layer comprises a plurality of second light-blocking lines extending in the first direction, the plurality of second light-blocking lines comprising a second light-blocking material, and
wherein an infrared light transmittance of the first light-blocking material is higher than an infrared light transmittance of the second light-blocking material.

2. The display apparatus as claimed in claim 1, wherein:
the plurality of first light-blocking lines are spaced from each other in a second direction crossing the first direction; and
the plurality of second light-blocking lines are spaced from each other in the second direction.

3. The display apparatus as claimed in claim 1, wherein at least one first light-blocking line among the plurality of first light-blocking lines and at least one second light-blocking line among the plurality of second light-blocking lines overlap each other in plan view.

4. The display apparatus as claimed in claim 1, wherein the first light-blocking material has a transmittance in a range of 90 % to 100 % for light having a wavelength of 940 nm.

5. The display apparatus as claimed in claim 1, wherein the first light-blocking material comprises at least one selected from among Lactam Black, Perlene Black, and Aniline Black.

6. The display apparatus as claimed in claim 1, wherein the second light-blocking material comprises at least one selected from among carbon black, black pigment, and black dye.

7. The display apparatus as claimed in claim 1, wherein the light control layer further comprises a third light-blocking layer under the second light-blocking layer and a fourth light-blocking layer under the third light-blocking layer, and
wherein:
the third light-blocking layer comprises a plurality of third light-blocking lines extending in the first direction; and
the fourth light-blocking layer comprises a plurality of fourth light-blocking lines extending in the first direction.

8. The display apparatus as claimed in claim 7, wherein the plurality of third light-blocking lines and the plurality of fourth light-blocking lines comprise substantially the same material as the second light-blocking material.

9. The display apparatus as claimed in claim 1, wherein the plurality of first light-blocking lines and the plurality of second light-blocking lines are in the main display area and the sub-display area.

10. The display apparatus as claimed in claim 9, wherein:
the light control layer further comprises a plurality of sub-light-blocking lines in the transmission area and extending in the first direction; and
the plurality of sub-light-blocking lines are on substantially the same layer as the plurality of first light-blocking lines and comprise substantially the same material as the first light-blocking material.

11. The display apparatus as claimed in claim 9, wherein:
the light control layer further comprises a sub-light-blocking pattern covering an entire surface of the transmission area; and
the sub-light-blocking pattern is on substantially the same layer as the plurality of first light-blocking lines and comprises substantially the same material as the first light-blocking material.

12. The display apparatus as claimed in claim 9, wherein the light control layer on the transmission area does not comprise any light-blocking material.

13. The display apparatus as claimed in claim 1, wherein:
the plurality of first light-blocking lines and the plurality of second light-blocking lines are in the main display area; and
the light control layer on the component area does not comprise any light-blocking material.

14. The display apparatus as claimed in claim 1, further comprising:
a signal wiring to transmit an electrical signal to:
a main pixel circuit electrically connected to the main light-emitting element; or
a sub-pixel circuit electrically connected to the sub-light-emitting element,
wherein the signal wiring extends in a second direction crossing the first direction, and
wherein the light control layer further comprises a vertical light-blocking line overlapping the signal wiring in plan view.

15. A display apparatus comprising:
a substrate comprising a component area and a main display area at least partially around the component area, the component area comprising a sub-display area and a transmission area;
a display layer comprising a main light-emitting element in the main display area and a sub-light-emitting element in the sub-display area; and
a light control layer on the display layer and comprising a plurality of first light-blocking lines extending in a first direction;
wherein the plurality of first light-blocking lines are in each of the main display area, the sub-display area, and the transmission area, and
wherein the plurality of first light-blocking lines have a transmittance in a range of 90 % to 100 % for light having a wavelength of 940 nm.

16. The display apparatus as claimed in claim 15, wherein each of the plurality of first light-blocking lines comprises at least one selected from among Lactam Black, Perlene Black, and Aniline Black.

17. The display apparatus as claimed in claim 15, wherein the light control layer further comprises a plurality of second light-blocking lines under the plurality of first light-blocking lines,
wherein the plurality of second light-blocking lines are in the main display area and the sub-display area, and
wherein an infrared light transmittance of the plurality of second light-blocking lines is lower than an infrared light transmittance of the plurality of first light-blocking lines.

18. The display apparatus as claimed in claim 17, wherein each of the plurality of second light-blocking lines comprises at least one selected from among carbon black, black pigment, and black dye.

19. An electronic apparatus comprising:
a display apparatus comprising a component area and a main display area at least partially around the component area, the component area comprising a sub-display area and a transmission area; and
a component to overlap the component area;
wherein the display apparatus comprises:
a substrate;
a display layer comprising a main light-emitting element in the main display area and a sub-light-emitting element in the sub-display area; and
a light control layer on the display layer and comprising a first light-blocking layer and a second light-blocking layer under the first light-blocking layer;
wherein:
the first light-blocking layer comprises a plurality of first light-blocking lines extending in a first direction, the plurality of first light-blocking lines comprising a first light-blocking material; and
the second light-blocking layer comprises a plurality of second light-blocking lines extending in the first direction, the plurality of second light-blocking lines comprising a second light-blocking material, and
wherein an infrared light transmittance of the first light-blocking material is higher than an infrared light transmittance of the second light-blocking material.

20. The electronic apparatus as claimed in claim 19, wherein the component comprises a camera or a sensor.
